(19) United States
(12) Patent Application Publication
(10) Pub. No.: US 2023/0189543 A1
(43) Pub. Date: Jun. 15, 2023

(54) LIGHT EMITTING ELEMENT AND DISPLAY DEVICE

(71) Applicants: Sony Group Corporation, Tokyo (JP); Sony Semiconductor Solutions Corporation, Kanagawa (JP)

(72) Inventors: Shoji Sudo, Tokyo (JP); Jun Yoshida, Kanagawa (JP)

(21) Appl. No.: 17/923,775

(22) PCT Filed: Jun. 14, 2021
(86) PCT No.: PCT/JP2021/022496

§ 371 Date: Nov. 7, 2022

(30) Foreign Application Priority Data
Jun. 23, 2020 (JP) 2020-107737

(51) Int. Cl. H10K 50/13

(52) U.S. Cl. CPC H10K 50/13; H10K 2101/40

(57) ABSTRACT

A light emitting element (10) of the present disclosure includes at least a first electrode (31), a second electrode (32), and a light emitting unit (30) sandwiched between the first electrode (31) and the second electrode (32), the light emitting unit 30 at least includes at least two light emitting layers (33a, 33b) that emit different colors and an intermediate layer (33d) located between the two light emitting layers (33a, 33b), the intermediate layer (33d) includes a first organic material (33e) having hole transport properties and a second organic material 33f having electron transport properties, and when a band gap energy of the first organic material (33e) is BGHTM and a band gap energy of a material having a maximum band gap energy among materials constituting two adjacent light emitting layers (33a, 33b) is BGmax, BGHTM-BGmax ≥ 0.2 eV is satisfied.

### FIELD

The present disclosure relates to a light emitting element and a display device.

### BACKGROUND

In recent years, a display device (organic EL display) using an organic electroluminescence (EL) element as a light emitting element has been developed. In this display device, for example, a light emitting unit including at least a light emitting layer and a second electrode (upper electrode, for example, cathode electrode) are formed on a first electrode (lower electrode, for example, anode electrode) formed separately for each pixel. Then, for example, each of a red light emitting element in which a light emitting unit that emits white light and a red color filter layer are combined, a green light emitting element in which a light emitting unit that emits white light and a green color filter layer are combined, and a blue light emitting element in which a light emitting unit that emits white light and a blue color filter layer are combined is provided as a sub-pixel, one pixel is constituted by these sub-pixels, and for example, light from the light emitting layer is emitted to the outside via the second electrode (upper electrode). An organic EL element (light emitting element) having a bipolar layer (intermediate layer) located between two light emitting layers is known from, for example, JP2006-172762 A. The bipolar layer (intermediate layer) contains a hole transporting material and an electron transporting material.

### CITATION LIST

### Patent Literature

Patent Literature 1: JP 2006-172762 A

### SUMMARY

### Technical Problem

Meanwhile, in order to achieve high luminance of a display device by achieving high efficiency of a light emitting element, it is important to suppress light emission to be excited and generated in an intermediate layer. However, in the technique disclosed in JP2006-172762 A, it is difficult to say that the suppression of light emission is sufficient.

Therefore present disclosure is, an object of the to provide a light emitting element having a configuration capable of achieving high efficiency, and a display device including the light emitting element.

### Solution to Problem

1. A light emitting element of the present disclosure for achieving the above purpose includes: at least
a first electrode;
a second electrode; and
a light emitting unit sandwiched between the first electrode and the second electrode,
wherein the light emitting unit at least includes at least two light emitting layers that emit different colors and an intermediate layer located between the two light emitting layers,
the intermediate layer contains a first organic material having hole transport properties and a second organic material having electron transport properties, and
when a band gap energy of the first organic material is BG_{HTM}, and a band gap energy of a material having a maximum band gap energy among materials constituting adjacent two light emitting layers is BGₘₐₓ,
BG_{HTM}-BGₘₐₓ ≥ 0.2 eV is satisfied.

A display device of the present disclosure for achieving the above purpose includes:
a plurality of light emitting elements arranged in a first direction and a second direction different from the first direction,
wherein each light emitting element includes at least
   a first electrode,
   a second electrode, and
   a light emitting unit sandwiched between the first electrode and the second electrode,
   the light emitting unit at least includes at least two light emitting layers that emit different colors and an intermediate layer located between the two light emitting layers,
   the intermediate layer contains a first organic material having hole transport properties and a second organic material having electron transport properties, and
   when a band gap energy of the first organic material is BG_{HTM}, and a band gap energy of a material having a maximum band gap energy among materials constituting adjacent two light emitting layers is BGₘₐₓ,
   BG_{HTM}-BGₘₐₓ ≥ 0.2 eV is satisfied.

### BRIEF DESCRIPTION OF DRAWINGS

FIG. 1A is a diagram illustrating an energy band gap of a light emitting unit constituting a light emitting element of Example 1.

FIG. 1B is a graph illustrating a result of obtaining an external quantum efficiency ratio of a light emitting element in Example 1 and Comparative Example 1.

FIG. 2 is a schematic partial cross-sectional view of a display device and the light emitting element of Example

FIG. 3 is a schematic partial cross-sectional view of Modification-1 of the display device and the light emitting element of Example 1.

FIG. 4 is a schematic partial cross-sectional view of Modification-2 of the display device and the light emitting element of Example 1.

FIG. 5 is a schematic partial cross-sectional view of Modification-3 of the display device and the light emitting element of Example 1.

FIG. 6 is a schematic partial cross-sectional view of a display device and a light emitting element of Example 2.

FIG. 7 is a schematic partial cross-sectional view of Modification-1 of the display device and the light emitting element of Example 2.

FIG. 8 is a schematic partial cross-sectional view of Modification-2 of the display device and the light emitting element of Example 2.

FIG. 9 is a schematic partial cross-sectional view of Modification-3 of the display device and the light emitting element of Example 2.

FIG. 10 is a schematic partial cross-sectional view of Modification-4 of the display device of Example 2 in which the optical path control unit includes a light reflecting member.

FIG. 11 is a conceptual diagram for explaining a relationship between a normal line LN passing through a center of a light emitting unit and a normal line LN′ passing through the center of the optical path control unit in the display device of Example 2.

FIG. 12A is a schematic diagram illustrating a positional relationship between the light emitting element and a reference point in the display device of Example 2.

FIG. 12B is a schematic view illustrating the positional relationship between the light emitting element and the reference point in the display device of Example 2.

FIG. 13A is a view schematically illustrating a positional relationship between a light emitting element and a reference point in a modification of the display device of Example 2.

FIG. 13B is a view schematically illustrating a positional relationship between a light emitting element and a reference point in a modification of the display device of Example 2.

FIG. 14A is a diagram schematically illustrating a change in D_{0-X} with respect to a change in D_{1-X} and a change in D_{0-Y} with respect to a change in D_{1-Y} in the display device of Example 2.

FIG. 14B is a diagram schematically illustrating the change in D_{0-X} with respect to the change in D_{1-X} and the change in D_{0-Y} with respect to the change in D_{1-Y} in the display device of Example 2.

FIG. 14C is a diagram schematically illustrating the change in D_{0-X} with respect to the change in D_{1-X} and the change in D_{0-Y} with respect to the change in D_{1-Y} in the display device of Example 2.

FIG. 14D is a diagram schematically illustrating the change in D_{0-X} with respect to the change in D_{1-X} and the change in D_{0-Y} with respect to the change in D_{1-Y} in the display device of Example 2.

FIG. 15A is a diagram schematically illustrating the change in D_{0-X} with respect to the change in D_{1-X} and the change in D_{0-Y} with respect to the change in D_{1-Y} in the display device of Example 2.

FIG. 15B is a diagram schematically illustrating the change in D_{0-X} with respect to the change in D_{1-X} and the change in D_{0-Y} with respect to the change in D_{1-Y} in the display device of Example 2.

FIG. 15C is a diagram schematically illustrating the change in D_{0-X} with respect to the change in D_{1-X} and the change in D_{0-Y} with respect to the change in D_{1-Y} in the display device of Example 2.

FIG. 15D is a diagram schematically illustrating the change in D_{0-X} with respect to the change in D_{1-X} and the change in D_{0-Y} with respect to the change in D_{1-Y} in the display device of Example 2.

FIG. 16A is a diagram schematically illustrating the change in D_{0-X} with respect to the change in D_{1-X} and the change in D_{0-Y} with respect to the change in D_{1-Y} in the display device of Example 2.

FIG. 16B is a diagram schematically illustrating the change in D_{0-X} with respect to the change in D_{1-X} and the change in D_{0-Y} with respect to the change in D_{1-Y} in the display device of Example 2.

FIG. 16C is a diagram schematically illustrating the change in D_{0-X} with respect to the change in D_{1-X} and the change in D_{0-Y} with respect to the change in D_{1-Y} in the display device of Example 2.

FIG. 16D is a diagram schematically illustrating the change in D_{0-X} with respect to the change in D_{1-X} and the change in D_{0-Y} with respect to the change in D_{1-Y} in the display device of Example 2.

FIG. 17A is a diagram schematically illustrating the change in D₀₋ₓ with respect to the change in D₁₋ₓ and the change in D_{0-Y} with respect to the change in D_{1-Y} in the display device of Example 2.

FIG. 17B is a diagram schematically illustrating the change in D₀₋ₓ with respect to the change in D₁₋ₓ and the change in D_{0-Y} with respect to the change in D_{1-Y} in the display device of Example 2.

FIG. 17C is a diagram schematically illustrating the change in D₀₋ₓ with respect to the change in D₁₋ₓ and the change in D_{0-Y} with respect to the change in D₁₋ₓ in the display device of Example 2.

FIG. 17D is a diagram schematically illustrating the change in D₀₋ₓ with respect to the change in D₁₋ₓ and the change in D₀₋ₓ with respect to the change in D₁₋ₓ in the display device of Example 2.

FIG. 18A is a conceptual diagram for describing a relationship among a normal line LN passing through a center of a light emitting unit, a normal line LN’ passing through a center of an optical path control unit, and a normal line LN” passing through a center of a wavelength selection unit in a display device of Example 3.

FIG. 18B is a conceptual diagram for describing the relationship among the normal line LN passing through the center of t he light emitting unit, the normal line LN’ passing through the center of the optical path control unit, and the normal line LN” passing through the center of the wavelength selection unit in the display device of Example 3.

FIG. 18C is a conceptual diagram for describing the relationship among the normal line LN passing through the center of the light emitting unit, the normal line LN’ passing through the center of the optical path control unit, and the normal line LN” passing through the center of the wavelength selection unit in the display device of Example 3.

FIG. 19 is a conceptual diagram for describing the relationship among the normal line LN passing through the center of the light emitting unit, the normal line LN’ passing through the center of the optical path control unit, and the normal line LN” passing through the center of the wavelength selection unit in the display device of Example 3.

FIG. 20A is a conceptual diagram for describing the relationship among the normal line LN passing through the center of the light emitting unit, the normal line LN’ passing through the center of the optical path control unit, and the normal line LN” passing through the center of the wavelength selection unit in the display device of Example 3.

FIG. 20B is a conceptual diagram for describing the relationship among the normal line LN passing through the center of the light emitting unit, the normal line LN’ passing through the center of the optical path control unit, and the normal line LN” passing through the center of the wavelength selection unit in the display device of Example 3.

FIG. 21. is a conceptual diagram for describing the relationship among the normal line LN passing through the center of the light emitting unit, the normal line LN’ passing through the center of the optical path control unit, and the normal line LN” passing through the center of the wavelength selection unit in the display device of Example 3.

FIG. 22A is a conceptual diagram of light emitting elements of a first example and a second example having a resonator structure in a display device of Example 4.

FIG. 22B is a conceptual diagram of the light emitting elements of the first example and the second example having the resonator structure in the display device of Example 4.

FIG. 23A is a conceptual diagram of light emitting elements of a third example and a fourth example having a resonator structure in a display device of Example 4.

FIG. 23B is a conceptual diagram of the light emitting elements of the third example and the fourth example having the resonator structure in the display device of Example 4.

FIG. 24A is a conceptual diagram of light emitting elements of a fifth example and a sixth example having a resonator structure in the display device of Example 4.

FIG. 24B is a conceptual diagram of the light emitting elements of the fifth example and the sixth example having the resonator structure in the display device of Example 4.

FIG. 25A is a conceptual diagram of a light emitting element of a seventh example having the resonator structure in the display device of Example 4.

FIG. 25B is a conceptual diagram of a light emitting element of an eighth example having the resonator structure.

FIG. 25C is a conceptual diagram of the light emitting element of the eighth example having the resonator structure.

FIG. 26A is a front view of a digital still camera illustrating an example in which the display device of the present disclosure is applied to a lens interchangeable single lens reflex type digital still camera.

FIG. 26B is a rear view of the digital still camera illustrating an example in which the display device of the present disclosure is applied to the lens interchangeable single lens reflex type digital still camera.

### DESCRIPTION OF EMBODIMENTS

Hereinafter, the present disclosure will be described based on examples with reference to the drawings, but the present disclosure is not limited to the examples, and various numerical values and materials in the examples are examples. Note that the description will be given in the following order.
1. General description of light emitting element of present disclosure and display device of present disclosure
2. Example 1 (light emitting element of present disclosure and display device of present disclosure)
3. Example 2 (modification of Example 2
4. Example 3 (modification of Examples 1 and 2)
5. Example 4 (modification of Examples 1 to 3)
6. Others

### General Description of Light Emitting Element of Present Disclosure and Display Device of Present Disclosure

In a light emitting element of the present disclosure or a light emitting element constituting a display device of the present disclosure (hereinafter, these light emitting elements may be collectively referred to as “light emitting elements or the like of the present disclosure ” for convenience), when a HOMO value of a first organic material is HOMO_{HTM}, a HOMO value of one adjacent light emitting layer is HOMO_{1,} and a HOMO value of the other adjacent light emitting layer is HOMO₂,
   | HOMO₂| ≤ | HOMO_{HTM}|≤ | HOMO₁| can be satisfied preferably,
   | HOMO₂ < |HOMO_{HTM}|≤|HOMO₁| can be satisfied more preferably,
   | HOMO₂| < |HOMO_{HTM}|< |HOMO₁ | can be satisfied,
and thus, the holes can be reliably moved from the other light emitting layer to the one light emitting layer.

In the light emitting element or the like of the present disclosure including the above preferred form, when a LUMO value of a second organic material is LUMO_{ETM}, a LUMO value of one adjacent light emitting layer is LUMO₁, and a LUMO value of the other adjacent light emitting layer is LUMO₂,
   |LUMO_{ETM}|≤ |LUMO₁| can be satisfied,
   |LUMO_{ETM}|≤ | LUMO₂| can be satisfied, preferably,
   |LUMO_{ETM}! < |LUMO₁ | can be satisfied,
   |LUMO_{ETM}! < |LUMO₂ |can be satisfied,
and thus, it is possible to suppress generation of charge accumulation between an intermediate layer and the light emitting layer, to stabilize the driving of the light emitting element, to suppress the decrease in movement measure of electron, and to suppress the increase in a driving voltage of the light emitting element.

Furthermore, in the light emitting element and the like of the present disclosure including the preferable form described above, when electron mobility of the second organic material is EM_{ETM} and electron mobility of a material constituting one adjacent light emitting layer is EM₁,
EM₁E ≤ EM_{ETM} can be satisfied, preferably,
EM₁E < EM_{ETM} can be satisfied,
and thus, the generation of the charge accumulation between the intermediate layer and one light emitting layer can be suppressed, and the driving of the light emitting element can be stabilized.

Furthermore, in the light emitting element and the like of the present disclosure including the preferred form described above, when a mass of the first organic material occupying the intermediate layer is M_{HTM} and a mass of the second organic material occupying the intermediate layer is M_{ETM},
M_{HTM} ≥ M_{ETM} can be satisfied,
and thus, the energy transfer to the intermediate layer can be suppressed.

In the following description, one light emitting layer may be referred to as a “first light emitting layer” for convenience, and the other light emitting layer may be referred to as a “second light emitting layer” for convenience.

In the light emitting element and the like of the present disclosure including the preferable form described above, the light emitting layer can include an organic electroluminescence layer. That is, the light emitting element and the like in the present disclosure including the various preferable forms described above can be configured by an organic electroluminescence element (organic EL element), and the display device of the present disclosure can be configured by an organic electroluminescence display device (organic EL display device).

Here, in other words, the display device of the present disclosure includes,
a first substrate, a second substrate, and
a plurality of light emitting elements positioned between the first substrate and the second substrate and arranged two-dimensionally,
in which each of the light emitting elements includes the light emitting element and the like of the present disclosure including the preferable forms described above, and
light from the light emitting unit is emitted to the outside via the second substrate or is emitted to the outside via the first substrate.

That is, the display device of the present disclosure can be a top emission type display device (top emission type display device) that emits light from the second substrate, or can be a bottom emission type display device (bottom emission type display device) that emits light from the first substrate.

Examples of a main material constituting the first light emitting layer can include a naphthalene derivative, an anthracene derivative, a pyrene derivative, a phenanthrene derivative, an aromatic amine, a carbazole derivative, and a triazine derivative, and when these materials are doped with a blue light emitting material such as TBP or FIrpic, blue light emission is obtained. Examples of a main material constituting the second light emitting layer can include a naphthalene derivative, an anthracene derivative, a pyrene derivative, a tetracene derivative, an aromatic amine, a carbazole derivative, and a triazine derivative, and when these materials are doped with a red light emitting dopant such as DBP or Ir(piq)₃, red light emission can be obtained. In addition, examples of the first organic material having hole transport properties can include naphthacene derivatives, phenanthrene derivatives, anthracene derivatives, pyrene derivatives, tetracene derivatives, carbazole derivatives, and aromatic amines, and examples of the second organic material having electron transport properties can include naphthacene derivatives, phenanthrene derivatives, anthracene derivatives, pyrene derivatives, tetracene derivatives, carbazole derivatives, fluoranthene derivatives, phenanthroline derivatives, pyridine derivatives, diazine derivatives, triazine derivatives, imidazole derivatives, and phenazine derivatives. Furthermore, examples of a preferable combination of (main material constituting first light emitting layer, main material constituting second light emitting layer, first organic material, second organic material) include (anthracene derivatives, anthracene derivatives, aromatic amine, anthracene derivatives), (anthracene derivatives, tetracene derivatives, aromatic amine, anthracene derivatives), (anthracene derivatives, carbazole derivatives, aromatic amine, carbazole derivatives), (carbazole derivatives, carbazole derivatives, aromatic amine, carbazole derivatives), and (carbazole derivatives, carbazole derivatives, carbazole derivatives, carbazole derivatives). Note that the present disclosure is applicable to a light emitting element using an organic substance or an organometallic compound, such as a fluorescent light emitting material, a phosphorescent light emitting material, or a thermally active delayed fluorescent material, and is also applicable to a light emitting element structure in which these materials are combined, and furthermore, the combination of emission colors is not limited to blue and red.

Examples of methods for forming the organic layer can include a physical vapor deposition method (PVD method) such as a vacuum vapor deposition method; a printing method such as a screen printing method or an inkjet printing method, a laser transfer method in which a laminated structure of a laser absorption layer and an organic layer formed on a transfer substrate is irradiated with a laser to separate the organic layer on the laser absorption layer and transfer the organic layer, and various coating methods. When the organic layer is formed on the basis of a vacuum vapor deposition method, for example, a so-called metal mask is used, and the organic layer can be obtained by depositing a material that has passed through an opening provided in the metal mask.

The HOMO value can be obtained on the basis of, for example, ultraviolet photoelectron spectroscopy (UPS method), and the LUMO value can be obtained from {(HOMO value) + E_{b}} . Furthermore, the band gap energy E_{b} can be obtained from the optically absorbed wavelength λ (optical absorption edge wavelength, in nm) on the basis of the following equation. In addition, the electron mobility can be measured on the basis of a Hall measurement method, or can be measured on the basis of a time of flight (TOF) method or impedance spectroscopy.

$${\text{E}}_{\text{b}} = \text{h} ν = \text{h} \left(\text{c} / λ\right) = 1239.8 / λ \left[\text{eV}\right]$$

As described above, the light emitting unit includes, from the first substrate side, the first electrode, at least two light emitting layers that emit light of different colors, and an intermediate layer located between the two light emitting layers (hereinafter, these layers may be collectively referred to as an “organic layer”) . The first electrode may be in contact with a part of the organic layer, or the organic layer may be in contact with a part of the first electrode. Specifically, a size of the first electrode may be smaller than that of the organic layer, or the size of the first electrode may be the same as that of the organic layer, but an insulating layer may be formed in a part between the first electrode and the organic layer, or the size of the first electrode may be larger than that of the organic layer. The size of the organic layer (light emitting unit) is the size of a region (light emitting region) where the first electrode and the organic layer are in contact with each other.

Then, the organic layer can emit white light, and in this case, the organic layer includes at least two light emitting layers that emit different colors as described above. Specifically, the organic layer may have a laminated structure in which three layers of a red light emitting layer that emits red light (wavelength: 620 nm to 750 nm), a blue light emitting layer that emits blue light (wavelength: 450 nm to 495 nm) , and a green light emitting layer that emits green light (wavelength: 495 nm to 570 nm) are laminated, and emits white light as a whole. Here, the blue light emitting layer corresponds to the first light emitting layer, the red light emitting layer corresponds to the second light emitting layer, and the intermediate layer is provided between the blue light emitting layer (first light emitting layer) and the red light emitting layer (second light emitting layer). The green light emitting layer may be referred to as a “third light emitting layer” for convenience. Alternatively, the organic layer may have a structure in which two layers of a blue light emitting layer (corresponding to a first light emitting layer) that emits blue light and a yellow light emitting layer (corresponding to a second light emitting layer) that emits yellow light are laminated, and emits white light as a whole. Alternatively, the organic layer may have a structure in which two layers of the blue light emitting layer (corresponding to the first light emitting layer) that emits blue light and an orange light emitting layer (corresponding to the second light emitting layer) that emits orange light are laminated, and emits white light as a whole.

Furthermore, in the display device of the present disclosure including these preferable forms, the size of the light emitting unit of the second light emitting element can be larger than the size of the light emitting unit of the first light emitting element and the size of the light emitting unit of the third light emitting element. Thus, an amount of light emission of the second light emitting element can be made larger than an amount of light emission of the first light emitting element and an amount of light emission of the third light emitting element, or the amount of light emission of the first light emitting element, the amount of light emission of the second light emitting element, and the amount of light emission of the third light emitting element can be made appropriate, and image quality can be improved. When it is assumed that the second light emitting element emits green light, the first light emitting element emits red light, the third light emitting element emits blue light, and the fourth light emitting element emits white light, a size of a light emitting region of each of the second light emitting element and the fourth light emitting element is preferably larger than a size of a light emitting region of each of the first light emitting element and the third light emitting element from the viewpoint of luminance. From the viewpoint of the life of the light emitting element, the size of the light emitting region of the third light emitting element is preferably larger than the sizes of the light emitting regions of the first light emitting element, the second light emitting element, and the fourth light emitting element. However, the present disclosure is not limited thereto.

The organic layer may be shared by a plurality of light emitting elements, or may be individually provided in each light emitting element.

An optical path control unit, for example, a lens member through which the light emitted from the light emitting unit passes may be provided. The optical path control unit will be described in detail in Example 2. In addition, the organic EL display device preferably has a resonator structure in order to further improve light extraction efficiency. The resonator structure will be described in detail in Example 4.

The light emitting element may include a wavelength selection unit in addition to the organic layer (light emitting unit) that emits white light. The light emitted from the light emitting unit enters the wavelength selection unit. In a case where the optical path control unit through which the light emitted from the light emitting unit passes is provided, the light emitted from the light emitting unit may pass through the wavelength selection unit and the optical path control unit in this order, or may pass through the optical path control unit and the wavelength selection unit in this order. The wavelength selection unit can be formed of, for example, a color filter layer, and the color filter layer is formed of a resin to which a colorant including a desired pigment or dye is added, and by selecting the pigment or dye, the light transmittance in a target wavelength region of red, green, blue, or the like is adjusted to be high and the light transmittance in other wavelength regions is adjusted to be low. Alternatively, the wavelength selection unit may be a wavelength selection element (a color filter layer having a conductor lattice structure in which a lattice-shaped hole structure is provided in a conductor thin film) to which photonic crystal or plasmon is applied. For example, referring to JP2008-177191 A, a thin film made of an inorganic material such as amorphous silicon, or a quantum dot can be used. Hereinafter, the color filter layer will be described as a representative of the wavelength selection unit, but the wavelength selection unit is not limited to the color filter layer.

The size of the wavelength selection unit (for example, a color filter layer) may be appropriately changed corresponding to the light emitted from the light emitting element, or in a case where a light absorbing layer (black matrix layer) is provided between the wavelength selection units (for example, color filter layers) of adjacent light emitting elements, the size of the light absorbing layer (black matrix layer) may be appropriately changed corresponding to the light emitted from the light emitting element. Furthermore, the size of the wavelength selection unit (for example, color filter layer) may be appropriately changed according to a distance (offset amount) d₀ (described later) between a normal line passing through the center of the light emitting unit and a normal line passing through the center of the color filter layer. A planar shape of the wavelength selection unit (for example, a color filter layer) may be the same as, similar to, approximate to, or different from a planar shape of the optical path control unit.

A red light emitting element (first light emitting element) is configured by combining the organic layer (light emitting unit) that emits white light and a red color filter layer (or a flattening layer that functions as a red color filter layer), a green light emitting element (second light emitting element) is configured by combining an organic layer (light emitting unit) that emits white light and a green color filter layer (or a flattening layer that functions as a green color filter layer), and a blue light emitting element (third light emitting element) is configured by combining an organic layer (light emitting unit) that emits white light and a blue color filter layer (or a flattening layer that functions as a blue color filter layer). The flattening layer will be described later. A light emitting element unit (one pixel) is configured by a combination of sub-pixels such as the red light emitting element, the green light emitting element, and the blue light emitting element. In some cases, the light emitting element unit (one pixel) may include a red light emitting element, a green light emitting element, a blue light emitting element, and a light emitting element that emits white (or a fourth color) (or a light emitting element that emits complementary color light). Examples of the arrangement of the first light emitting element, the second light emitting element, and the third light emitting element in the pixel include a delta arrangement, a stripe arrangement, a diagonal arrangement, a rectangle arrangement, and a pentile arrangement. The wavelength selection units may be arranged in a delta array, a stripe array, a diagonal array, a rectangle array, or a pentile array in accordance with the arrangement of the pixels (or sub-pixels).

Specifically, the first electrode, the organic layer, and the second electrode are sequentially formed on the base. A base is formed on or above the first substrate. Examples of the material constituting the base include insulating materials such as SiO₂, SiN, and SiON. The base can be formed by a forming method suitable for the material constituting the base, specifically, for example, a known method such as various CVD methods, various coating a sputtering method methods, various PVD methods including and a vacuum vapor deposition method, various printing methods such as a screen printing method, a plating method, an electrodeposition method, an immersion method, and a sol-gel method.

A drive circuit is provided below or under the base, although not limited thereto. The drive circuit includes, for example, a transistor (specifically, for example, a MOSFET) formed on a silicon semiconductor substrate constituting the first substrate, and a thin film transistor (TFT) provided on various substrates constituting the first substrate. The transistor and the TFT constituting the drive circuit may be connected to the first electrode via a contact hole (contact plug) formed in the base or the like. The drive circuit can have a known circuit configuration. For example, the second electrode is connected to the drive circuit via a contact hole (contact plug) formed in the base or the like at an outer peripheral portion (specifically, the outer peripheral portion of the pixel array unit) of the display device.

The first substrate or the second substrate can be made of a silicon semiconductor substrate, a high strain point glass substrate, a soda glass (Na₂O • CaO • SiO₂) substrate, a borosilicate glass (Na₂O • B₂O₃ • SiO₂) substrate, a forsterite (2MgO · SiO₂) substrate, a lead glass (Na₂O · PbO · SiO₂) substrate, various glass substrates having an insulating material layer formed on a surface thereof, a quartz substrate, a quartz substrate having an insulating material layer formed on a surface thereof, and an organic polymer (has a form of a polymer material such as a flexible plastic film, a plastic sheet, or a plastic substrate made of a polymer material) polymethyl methacrylate (polymethyl exemplified by methacrylate, PMMA), polyvinyl alcohol (PVA), polyvinylphenol (PVP), polyethersulfone (PES), polyimide, polycarbonate, polyethylene terephthalate (PET), and polyethylene naphthalate (PEN). The materials constituting the first substrate and the second substrate may be the same or different. However, in the case of the top emission type display device, the second substrate is required to be transparent to light from the light emitting element, and in the case of the bottom emission type display device, the first substrate is required to be transparent to light from the light emitting element.

The first electrode is provided for each light emitting element. The second electrode may be a common electrode in the plurality of light emitting elements. That is, the second electrode may be a so-called solid electrode. The first substrate is disposed below or under the base, and the second substrate is disposed above the second electrode. A light emitting element is formed on the first substrate side, and the light emitting unit is provided on the base.

When the first electrode functions as an anode electrode, examples of the material constituting the first electrode can include a metal or an alloy (for example, an Ag—Pd—Cu alloy containing silver as a main component and containing 0.3 mass% to 1 mass% of palladium (Pd) and 0.3 mass% to 1 mass of copper (Cu), an Al—Nd alloy, an Al—Cu alloy, or an Al—Cu—Ni. alloy) having a high work function such as platinum (Pt), gold (Au), silver (Ag), chromium (Cr), tungsten (W), nickel (Ni), copper (Cu), iron (Fe), cobalt (Co), or tantalum (Ta). Furthermore, in the case of using a conductive material having a small work function value and a high light reflectance, such as aluminum (Al) and an alloy containing aluminum, the conductive material can be used as an anode electrode by improving hole injection characteristics by providing an appropriate hole injection layer or the like. The thickness of the first electrode may be 0.1 µm to 1 µm, for example. Alternatively, when a light reflecting layer constituting a resonator structure to be described later is provided, the first electrode is required to be transparent to light from the light emitting element. Therefore, examples of the materials constituting the first electrode can include various transparent conductive materials such as a transparent conductive material having indium oxide, indium-tin oxide (ITO, Indium Tin Oxide, Sn-doped In₂O₃, crystalline ITO and amorphous ITO), indium-zinc oxide (IZO, Indium Zinc Oxide), indium-gallium oxide (IGO), indium-doped gallium-zinc oxide (IGZO, In-GaZnO₄) , IFO (F-doped In₂O₃), ITiO (Ti-doped In₂O₃), InSn, InSnZnO, tin, oxide (SnO₂), ATO (Sb-doped SnO₂), FTO (F-doped SnO₂), zinc oxide (ZnO), aluminum oxide-doped zinc oxide (AZO), gallium doped zinc oxide (GZO), B-doped ZnO, AlMgZnO (aluminum oxide and magnesium oxide doped zinc oxide), antimony oxide, titanium oxide, NiO, a spinel type oxide, an oxide having a YbFe₂O₄ structure, a gallium oxide, a titanium oxide, a niobium oxide, a nickel oxide, or the like as a base layer. Alternatively, a transparent conductive material having excellent hole injection characteristics, such as an oxide of indium and tin (ITO) or an oxide of indium and zinc (IZO), may be laminated on a dielectric multilayer film or a reflective film having high light reflectivity, such as aluminum (Al) or an alloy thereof (for example, an Al—Cu—Ni alloy). Meanwhile, in a case where the first electrode functions as a cathode electrode, it is desirable to include a conductive material having a small work function value and a high light reflectance. However, the first electrode can also be used as a cathode electrode by improving electron injection characteristics by providing an appropriate electron injection layer in a conductive material having a high light reflectance used as an anode electrode.

In a case where the second electrode functions as a cathode electrode, a material (semi-light transmissive material or light transmissive material) constituting the second electrode is desirably constituted by a conductive material having a small work function value so as to transmit emission light and to efficiently inject electrons into the organic layer (light emitting layer), examples thereof can include metals or alloys having a small work function such as aluminum (Al), silver (Ag), magnesium (Mg), calcium (Ca), sodium (Na), strontium (Sr), an alkali metal or an alkaline earth metal and silver (Ag) [For example, an alloy of magnesium (Mg) and silver (Ag) (Mg-Ag alloy)], an alloy of magnesium-calcium (Mg-Ca alloy), and an alloy of aluminum (Al) and lithium (Li) (Al—Li alloy), and among them, a Mg—Ag alloy is preferable, and a volume ratio of magnesium to silver can be exemplified by Mg:Ag = 5:1 to 30:1. Alternatively, as the volume ratio of magnesium to calcium, Mg:Ca = 2:1 to 10:1 can be exemplified. The thickness of the second electrode may be, for example, 4 nm to 50 nm, preferably 4 nm to 20 nm, more preferably 6 nm to 12 nm. Alternatively, at least one material selected from the group consisting of Ag—Nd—Cu, Ag—Cu, Au, and Al—Cu can be mentioned. Alternatively, the second electrode may have a laminated structure of the above-described material layer and a so-called transparent electrode (for example, a thickness of 3 × 10⁻⁸ m to 1 × 10⁻⁶ m) made of, for example, ITO or IZO from the organic layer side. A bus electrode (auxiliary electrode) made of a low-resistance material such as aluminum, an aluminum alloy, silver, a silver alloy, copper, a copper alloy, gold, or a gold alloy may be provided for the second electrode to reduce the resistance of the second electrode as a whole. An average light transmittance of the second electrode is desirably 50% to 90%, and preferably 60% to 90%. Meanwhile, when the second electrode functions as an anode electrode, it is desirable that the second electrode is made of a conductive material that transmits emitted light as necessary and has a large work function value.

Examples of a method for forming the first electrode and the second electrode can include: a vapor deposition method including an electron beam vapor deposition method, a hot filament vapor deposition method, and a vacuum vapor deposition method, a sputtering method, a chemical vapor deposition method (CVD method), an MOCVD method, and a combination of an ion plating method and an etching method; various printing methods such as a screen printing method, an inkjet printing method, and a metal mask printing method; a plating method (electroplating method or electroless plating method); a lift-off method; a laser ablation method; and a sol-gel method. According to various printing methods and plating methods, it is possible to directly form the first electrode and the second electrode having a desired shape (pattern). When the second electrode is formed after the organic layer is formed, it is particularly preferable to form the second electrode on the basis of a film forming method in which the energy of film-formed particles is small such as a vacuum vapor deposition method or a film forming method such as an MOCVD method from the viewpoint of preventing occurrence of damage to the organic layer. When the organic layer is damaged, there is a possibility that a non-light emitting pixel (or a non-light emitting subpixel) called a “blinking point” due to generation of a leakage current occurs.

A protective layer is preferably formed so as to cover the second electrode. A flattening layer may be further formed on or above the protective layer. As described above, the flattening layer functioning as the wavelength selection unit may be provided.

A light shielding portion may be provided between the light emitting element and the light emitting element. Specific examples of the light shielding material constituting the light shielding portion include materials capable of shielding light, such as titanium (Ti), chromium (Cr), tungsten (W), tantalum (Ta), aluminum (Al), and MoSi₂. The light shielding portion can be formed by a vapor deposition method including an electron beam vapor deposition method, a hot filament vapor deposition method, and a vacuum vapor deposition method, a sputtering method, a CVD method, an ion plating method, or the like.

A light absorbing layer (black matrix layer) may be formed between the wavelength selection unit and the wavelength selection unit, above the wavelength selection unit and the wavelength selection unit, or between adjacent optical path control units, and thus, occurrence of color mixture between adjacent light emitting elements can be reliably suppressed. The light absorbing layer (black matrix layer) includes, for example, a blackresin film (specifically, for example, a black polyimide-based resin) mixed with a black colorant and having an optical density of 1 or more, or includes a thin film filter using interference of a thin film. The thin film filter is formed by laminating two or more thin films made of metal, metal nitride, or metal oxide, for example, and attenuates light using interference of the thin films. Specific examples of the thin film filter include a thin film filter in which Cr and chromium (III) oxide (Cr₂O₃) are alternately laminated.

Examples of the material constituting the protective layer and the flattening layer include an acrylic resin and an epoxy resin, and various inorganic materials (for example, SiO₂, SiN, SiON, SiC, amorphous silicon (α-Si), Al₂O₃, TiO₂). The protective layer and the flattening layer may have a single-layer configuration or may include a plurality of layers. The protective layer and the flattening layer can be formed by a known method such as various CVD methods, various coating methods, various PVD methods including a sputtering method and a vacuum vapor deposition method, and various printing methods such as a screen printing method. Furthermore, as a method for forming the protective layer and the flattening layer, an atomic layer deposition (ALD) method can also be adopted. The protective layer and the flattening layer may be shared by a plurality of light emitting elements, or may be individually provided in each light emitting element.

The flattening layer and the second substrate are bonded to each other with a resin layer (sealing resin layer) interposed therebetween, for example. Examples of the material constituting the resin layer (sealing resin layer) include thermosetting adhesives such as an acrylic adhesive, an epoxy adhesive, a urethane adhesive, a silicone adhesive, and a cyanoacrylate adhesive, and ultraviolet curing adhesives. The resin layer (sealing resin layer) may also serve as the flattening layer.

As described above, in some cases, the flattening layer may have a function as a color filter layer. The flattening layer may be formed of a known color resist material. In the light emitting element that emits white light, a transparent filter may be disposed. When the flattening layer also functions as a color filter layer in this manner, the organic layer and the flattening layer (color filter layer) are close to each other, and thus, color mixing can be effectively prevented even when the angle of light emitted from the light emitting element is widened, and viewing angle characteristics are improved. However, the color filter layer may be provided on or above the flattening layer or below or under the flattening layer independently of the flattening layer.

On the outermost surface (specifically, for example, the outer surface of the second substrate) of the display device from which light is emitted, an ultraviolet absorbing layer, a contamination preventing layer, a hard coat layer, and an antistatic layer may be formed, or a protective member (for example, cover glass) may be disposed.

In the display device, an insulating layer, an interlayer insulating layer, and an interlayer insulating material layer are formed, and examples of insulating materials constituting these layers can include: SiOₓ-based materials (materials constituting a silicon-based oxide film) such as SiO₂, NSG (non-doped silicate glass), BPSG (boron-phosphorus silicate glass), PSG, BSG, AsSG, SbSG, PbSG, SOG (spin-on glass), low temperature oxide (LTO), low temperature CVD-SiO_{2,} low-melting-point glass, and glass paste; SiN-based material including SiON-based material; and SiOC; SiOF; SICN. Alternatively, examples of the insulating materials can include inorganic insulating materials such as titanium oxide (TiO₂), tantalum oxide (Ta₂O₅), aluminum oxide (Al₂O₃) , magnesium oxide (MgO), chromium oxide (CrOₓ) , zirconium oxide (ZrO₂), niobium oxide (Nb₂O₅), tin oxide (SnO₂), and vanadium oxide (VOₓ) . Alternatively, examples of the insulating materials can include various resins such as a polyimide-based resin, an epoxy-based resin, and an acryl-based resin, and low dielectric constant insulating materials (for example, a material having a dielectric constant k (= ε/εₒ) of 3.5 or less, and specifically, and specific examples thereof can include fluorocarbon, a cycloperfluorocarbon polymer, benzocyclobutene, a cyclic fluorine-based resin, polytetrafluoroethylene, amorphoustetrafluoro ethylene, polyaryl ether, fluorinated aryl ether, fluorinated polymide amorphous carbon parylene (polyparaxylylene), and fluorinated fullerene) such as SiOCH, organic SOG and a fluorine-based resin, and Silk (is a trademark of The Dow Chemical Co. and is a coating-type low-dielectric-constant interlayer insulating film material) and Flare (is a trademark of Honeywell Electronic Materials Co. and Polyallyl ether (PAE)-based material) can also be exemplified. These can be used alone or in appropriate combination. In some cases, the base may be made of the material described above. The insulating layer, the interlayer insulating material layer, and the base can be formed on the basis of known methods such as various CVD methods, various coating methods, various PVD methods including a sputtering method and a vacuum vapor deposition method, and various printing methods such as a screen printing method, a plating method, an electrodeposition method, an immersion method, and a sol-gel method.

The display device can be used as, for example, a monitor device constituting a personal computer, or can be used as a television receiver, a mobile phone, a personal digital assistant (PDA), a monitor device incorporated in a game apparatus, or a display device incorporated in a projector. Alternatively, the display device can be applied toan electronic viewfinder (Electronic View Finder, EVF), a head mounted display (Head Mounted Display, HMD) , eyewear, AR glasses, and EVR, and can be applied to a display device for virtual reality (VR) , mixed reality (MR), or augmented reality (AR). Alternatively, the display device can configure an image display device in an electronic book, an electronic paper such as an electronic newspaper, a bulletin board such as a signboard, a poster, or a blackboard, a rewritable paper as a substitute for printer paper, a display unit of a home appliance, a card display unit such as a loyalty card, an electronic advertisement, or an electronic POP advertising. Using the display device of the present disclosure as a light emitting device, various lighting devices including a backlight device for a liquid crystal display device and a planar light source device can be configured.

### Example 1

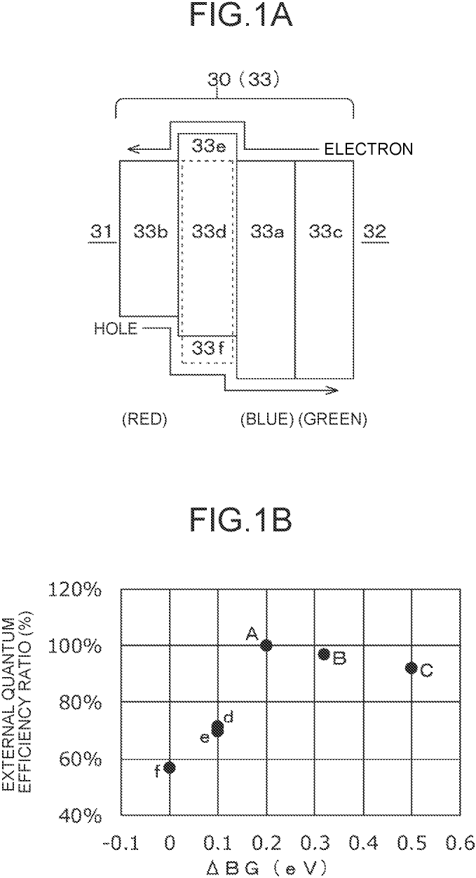

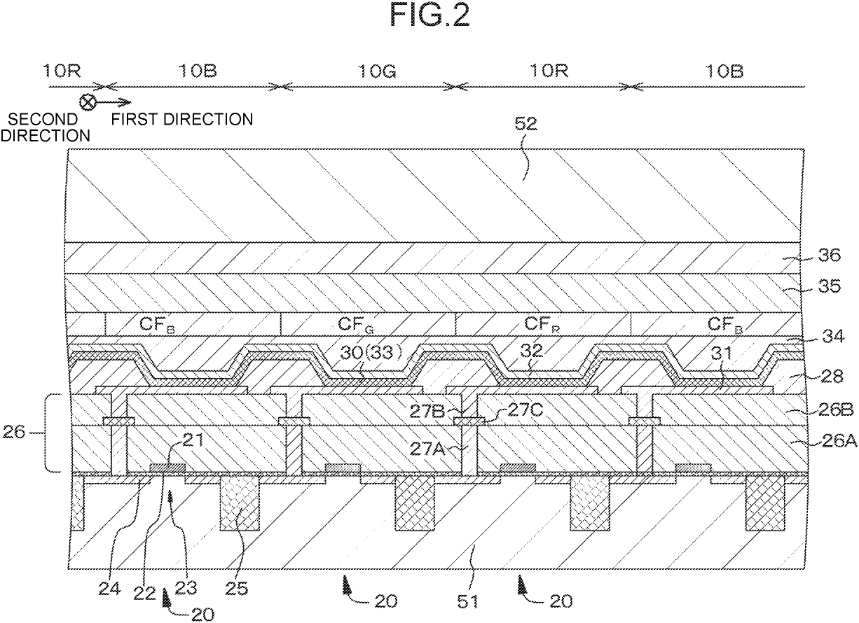

Example 1 relates to the light emitting element of the present disclosure and the display device of the present disclosure. FIG. 1A illustrates an energy band gap diagram of the light emitting unit constituting the light emitting element of Example 1, and FIG. 2 illustrates a schematic partial cross-sectional view of the display device and the light emitting element of Example 1. In Example 1 or Examples 2 to 4 described later, the light emitting element includes an organic electroluminescence element (organic EL element), and the display device includes an organic electroluminescene display device (organic EL display device), and is an active matrix display device. The light emitting layer includes an organic electroluminescence layer.

The light emitting element 10 of Example 1 or Examples 2 to 4 described later includes: at least
a first electrode 31 made of aluminum having a thickness of 0.1 µm;
a second electrode 32 including a LiF layer having a thickness of 0.3 nm, a Ca layer having a thickness of 5 nm, and a Mg—Ag alloy layer having a thickness of 5 nm; and
a light emitting unit 30 (organic layer 33) sandwiched first the second electrode 32, between the first electrode 31 and the second electrode 32,
   in which the light emitting unit 30 (organic layer 33) at least includes at least two light emitting layers (first light emitting layer 33a, second light emitting layer 33b) that emit different colors, and an intermediate layer 33d located between the two light emitting layers 33a and 33b, and
   the intermediate layer 33d contains a first organic material 33e having hole transport properties and a second organic material 33f having electron transport properties.

When a band gap energy of the first organic material 33e is BG_{HTM}, and the band gap energy of a material having the maximum band gap energy among the materials constituting two adjacent light emitting layers (first light emitting layer 33a, second light emitting layer 33b) is BGₘₐₓ,

ΔBG = BG_{HTM}-BGₘₐₓ ≥ 0.2 eV is satisfied.

In the energy band gap diagram of the light emitting unit illustrated in FIG. 1A, the energy band gaps of the first light emitting layer 33a, the second light emitting layer 33b, the third light emitting layer 33c to be described later, and the first organic material 33e are illustrated by solid lines, and the energy band gap of the second organic material 33f is illustrated by dotted lines.

In addition, the display device of Example 1 or Examples 2 to 4 described later includes a plurality of light emitting elements arranged in a first direction and a second direction different from the first direction,
in which each light emitting element includes: at least
   a first electrode 31;
   a second electrode 32; and
   a light emitting unit 30 (organic layer 33) sandwiched first the second electrode 32, between the first electrode 31 and the second electrode 32,
the light emitting unit 30 (organic layer 33) at least includes at least two light emitting layers (first light emitting layer 33a, second light emitting layer 33b) that emit different colors and an intermediate layer 33d located between the two light emitting layers 33a and 33b,
the intermediate layer 33d contains a first organic material 33e having hole transport properties and a second organic material 33f having electron transport properties, and
when the band gap energy of the first organic material 33e is BG_{HTM,}and the band gap energy of the material having the maximum band gap energy among the materials constituting the adjacent two light emitting layers (first light emitting layer 33a, second light emitting layer 33b) is BGₘₐₓ,
BG_{HTM}-BGₘₐₓ ≥ 0.2 eV is satisfied.

Alternatively, in other words, the display device of Example 1 or Examples 2 to 4 described later includes:
a first substrate 51, a second substrate 52, and
a plurality of light emitting elements positioned between the first substrate 51 and the second substrate 52 and arranged two-dimensionally,
in which each light emitting element is constituted by a light emitting element 10 of Example 1 or Examples 2 to 4 described later, and
light from the light emitting unit 30 is emitted to the outside via the second substrate 52 or is emitted to the outside via the first substrate 51. Specifically, in Example 1 or Examples 2 to 4 described later, the light is emitted to the outside via the second substrate 52. That is, the display device of Example 1 is a top emission type display device that emits light from the second substrate 52.

As described above, the light emitting unit 30 (organic layer 33) includes at least two light emitting layers (first light emitting layer 33a, second light emitting layer 33b) that emit different colors, and emits white light. Specifically, the organic layer 33 includes a blue light emitting layer (first light emitting layer 33a) that emits blue light (wavelength: 450 nm to 495 nm), a red light emitting layer (second light emitting layer 33b) that emits red light (wavelength: 620 nm to 750 nm), and an intermediate layer 33d provided between the blue light emitting layer (first light emitting layer 33a) and the red light emitting layer (the second light emitting layer 33b). In addition, a green light emitting layer (third light emitting layer 33c) that emits green light (wavelength: 495 nm to 570 nm) is provided on a side opposite to the intermediate layer 33d in contact with the blue light emitting layer (first light emitting layer 33a), and these four layers are laminated.

The organic layer 33 is shared by a plurality of light emitting elements. Then, the combination of the organic layer 33 (light emitting unit 30) that emits white light and the wavelength selection unit (for example, the red color filter layer CF_{R}) that passes red light forms the red light emitting element 10R, a combination of the organic layer 33 (light emitting unit 30) that emits white light and the wavelength selection unit (for example, the green color filter layer CF_{G}) that passes green light forms the green light emitting element 10G, and a combination of the organic layer 33 (light emitting unit 30) that emits white light and the wavelength selection unit (for example, the blue color filter layer CF_{B}) that passes blue light forms the blue light emitting element 10B. Then, a combination of sub-pixels such as the red light emitting element 10R, the green light emitting element 10G, and the blue light emitting element 10B constitutes a light emitting element unit (one pixel). In some cases, the light emitting element unit (one pixel) may include the red light emitting element 10R, the green light emitting element 10G, the blue light emitting element 10B, and a light emitting element that emits white (or fourth color) (or a light emitting element that emits complementary color light).

In the display device of Example 1, the arrangement of the first light emitting element 10G, the second light emitting element 10R, and the third light emitting element 10B is a delta arrangement, but the present disclosure is not limited thereto.

Specifically, the first electrode 31, the organic layer 33, and the second electrode 32 are sequentially formed on the base 26. The base 26 is formed on first substrate 51. Examples of the material constituting the base 26 include insulating materials such as SiO₂, SiN, and SiON.

A drive circuit is provided below or under the base 26. The drive circuit includes, for example, a transistor (specifically, for example, a MOSFET) formed on a silicon semiconductor substrate constituting the first substrate 51. The transistor constituting the drive circuit and the first electrode 31 are connected via, for example, a contact hole (contact plug) 27A, a pad portion 27C, and a contact hole (contact plug) 27B formed in the base 26.

The first electrode 31 is provided for each light emitting element. The organic layer 33 is commonly provided in the light emitting element. The second electrode 32 is a common electrode in the plurality of light emitting elements. That is, the second electrode 32 is a so-called solid electrode. The first substrate 51 is disposed below the base 26, and the second substrate 52 is disposed above the second electrode 32. The light emitting element is formed on the first substrate side, and the light emitting unit 30 is provided on the base 26.

A protective layer 34 made of SiN and having a thickness of 1 µm is formed so as to cover the second electrode 32, and the wavelength selection unit [color filter layer CF (CF_{R}, CF_{G}, CF_{B})] made of a known material is formed on the protective layer 34 by a known method. A flattening layer 35 is formed on the wavelength selection unit (color filter layer CF), and the flattening layer 35 and the second substrate 52 are bonded to each other with a resin layer (sealing resin layer) 36 interposed therebetween, for example. The outer shapes of the light emitting unit 30 and the color filter layer CF are, for example, circular, but are not limited to such shapes. Examples of the material constituting the sealing resin layer 36 include thermosetting adhesives such as an acrylic adhesive, an epoxy-based adhesive, a urethane-based adhesive, a silicone-based adhesive, and a cyanoacrylate-based adhesive, and ultraviolet-curable adhesives. The color filter layer CF is an on-chip color filter layer (OCCF) formed on the first substrate side. As a result, a distance between the organic layer 33 and the color filter layer CF can be shortened, and the light emitted from the organic layer 33 can be prevented from entering the adjacent color filter layer CF of another color to cause color mixing. In some cases, the flattening layer 35 may be omitted, and the color filter layer CF may be bonded to the second substrate 52 via the sealing resin layer 36.

In the light emitting element 10 of Examples 1 to 4 including the organic EL element, as described above, the organic layer 33 has a laminated structure of the red light emitting layer 33b, the intermediate layer 33d, the blue light emitting layer 33a, and the green light emitting layer 33c. As described above, one light emitting element unit (one pixel) includes three light emitting elements of the red light emitting element 10R, the green light emitting element lOG, and the blue light emitting element 10B. The organic layer 33 constituting the light emitting element 10 emits white light, and each of the light emitting elements 10R, 10G, and 10B includes a combination of the organic layer 33 emitting white light and the color filter layers CF_{R} CF_{G}, and CF_{B}. As described above, the red light emitting element 10R to display red is provided with the red color filter layer CF_{R}, the green light emitting element 10G to display green is provided with the green color filter layer CF_{G}, and the blue light emitting element 10B to display blue is provided is with the blue color filter layer CF_{B}. The red light emitting element 10R, the green light emitting element 10G, and the blue light emitting element 10B have substantially the same configuration and structure except for the configuration of the color filter layer and the arrangement position of the light emitting layer in the thickness direction of the organic layer. The number of pixels is, for example, 1920 x 1080, one light emitting element (display element) constitutes one sub-pixel, and the number of light emitting elements (specifically, organic EL elements) is three times the number of pixels.

A drive circuit is provided below the base 26 made of SiOz formed on the basis of the CVD method. The drive circuit can have a known circuit configuration. The drive circuit includes a transistor (specifically, the MOSFET) formed on a silicon semiconductor substrate corresponding to the first substrate 51. The transistor 20 including the MOSFET includes a gate insulating layer 22 formed on the first substrate 51, a gate electrode 21 formed on the gate insulating layer 22, a source/drain region 24 formed on the first substrate 51, a channel formation region 23 formed between the source/drain regions 24, and an element isolation region 25 surrounding the channel formation region 23 and the source/drain region 24 . The base 26 includes a lower interlayer insulating layer 26A and an upper interlayer insulating layer 26B.

In the light emitting element 10, the transistor 20 and the first electrode 31 are electrically connected via a contact plug 27A provided on the lower interlayer insulating layer 26A, a pad portion 27C provided on the lower interlayer insulating layer 26A, and a contact p lug 278 provided on the upper interlayer insulating layer 26B. In the drawings, one transistor 20 is illustrated for one drive circuit.

The second electrode 32 is connected to the drive circuit (light emitting element driving unit) via a contact hole (contact plug) not illustrated formed in the base 26 aT. the outer peripheral portion (specifically, the outer peripheral portion of the pixel array unit) of the display device. In the outer peripheral portion of the display device, an auxiliary electrode connected to the second electrode 32 may be provided below the second electrode 32, and the auxiliary electrode may be connected to the drive circuit.

The first electrode 31 functions as an anode electrode, and the second electrode 32 functions as a cathode electrode. The first electrode 31 includes a light reflecting material layer, specifically, for example, a laminated structure of an Al—Nd alloy layer, an Al—Cu alloy layer, an Al—Ti alloy layer, and an ITO layer, and the second electrode 32 includes a transparent conductive material such as ITO. The first electrode 31 is formed on the base 26 on the basis of a combination of a vacuum vapor deposition method and an etching method. In addition, the second electrode 32 is formed by a film forming method in which the energy of_ film-formed particles is small, such as a vacuum vapor deposition method, and is not patterned. The organic layer 33 is also not patterned. However, the present disclosure :_s not limited thereto.

The light emitting element 10 has a resonator structure in which the organic layer 33 is a resonance unit. In order to appropriately adjust a distance (specifically, a distance from a light emitting surface to the first electrode 31 and the second electrode 32) from the light emitting surface to a reflecting surface, the thickness of the organic layer 33 is preferably 8 x 10⁻⁸ m or more and 5 x 10⁻⁷ m or less, and more preferably 1.5 s 10 ^{\~7} m or more and 3.5 x 10⁻⁷ m or less. In the organic EI: display device having the resonator structure, actually, the red light emitting element 10R causes red light emitted from the light emitting layer to resonate, and emits reddish light (light having a light spectrum peak in a red region) from the second electrode 32. In addition, the green light emitting element 10G causes green light emitted from the light emitting layer to resonate, and emits greenish light (light, having a light spectrum peak in a green region) from the second electrode 32. Furthermore, the blue light emitting element 10B causes blue light emitted from the light emitting layer to resonate, and emits bluish light (light having a light spectrum peak in a blue region) from the second electrode 32.

Hereinafter, an outline of a method for manufacturing the light emitting element 10 of Example 1 illustrated in FIG. 2 will be described.

### Step-100

First, the drive circuit is formed on the silicon semiconductor substrate (first substrate 51) on the basis of a known MOSFET manufacturing process.

### Step-110

Next, the lower interlayer insulating layer 26A is formed on the entire surface by a CVD method. Then, a connection hole is formed in a portion of the lower interlayer insulating layer 26A located above one of the source/drain regions 24 of the transistor 20 on the basis of a photolithography technique and an etching technique, a conductive material layer is formed on the lower interlayer insulating layer 26A including the connection hole on the basis of, for example, a sputtering method, and the conductive material layer is patterned on the basis of a photolithography technique and an etching technique, and thus, the contact hole (contact plug) 27A and the pad portion 27C can be formed.

### Step-120

Then, the upper interlayer insulating layer 26B is formed on the entire surface, a connection hole is formed in a portion of the upper interlayer insulating layer 26B located above the desired pad portion 27C on the basis of a photolithography technique and an etching technique, a conductive material layer is formed on the upper interlayer insulating layer 26B including the connection hole on the basis of, for example, a sputtering method, and then the conductive material layer is patterned on the basis of a photolithography technique and an etching technique, and thus, the first electrode 31 can be formed on a part of the base 26. The first electrode 31 is separated for each light emitting element. In addition, a contact hole (contact plug) 27B electrically connecting the first electrode 31 and the transistor 20 can be formed in the connection hole.

### Step-130

Next, for example, an insulating layer 28 is formed on the entire surface on the basis of a CVD method, and the insulating layer 28 is left on the base 26 between the first electrode 31 and the first electrode 31 on the basis of a photolithography technique and an etching technique.

### Step-140

Thereafter, the organic layer 33 is formed on the first electrode 31 and the insulating layer 28 by, for example, a PVD method such as a vacuum vapor deposition method or a sputtering method, a coating method such as a spin coating method or a die coating method, or the like. In some cases, the organic layer 33 may be patterned into a desired shape.

### Step-150

Next, the second electrode 32 is formed on the entire surface on the basis of, for example, a vacuum vapor deposition method or the like. In some cases, the second electrode 32 may be patterned into a desired shape. In this way, the organic layer 33 and the second electrode 32 can be formed on the first electrode 31.

### Step-160

Thereafter, the protective layer 34 is formed on the entire surface on the basis of a coating method, and then the top surface of the protective layer 34 is planarized. Since the protective layer 34 can be formed on the basis of a coating method, there are few restrictions on a processing process, a material selection width is wide, and a high refractive index material can be used. Thereafter, the color filter layer CF (CF_{R}, CF_{G}, CF_{B}) is formed on the protective layer 34 by a known method.

### Step-170

Then, the flattening layer 35 is formed on the color filter layer CF. Thereafter, the flattening layer 35 and the second substrate 52 are bonded to each other by the sealing resin layer 36 made of an acrylic adhesive. In this way, the light emitting element (organic EL element) 10 and the display device of Example 1 illustrated in FIGS. 1 and 2 can be obtained. As described above, by adopting a so-called OCCF type in which the color filter layer CF is provided on the first substrate side instead of providing the color filter layer CF on the second substrate side, the distance between the organic layer 33 and the color filter layer CF can be shortened.

Light emitting elements of Examples and light emitting elements of Comparative Examples having the same configuration and structure except that materials used as the first organic materials are different were prototyped. The material constituting the first light emitting layer, the material constituting the second light emitting layer, the material constituting the third light emitting layer, and the second organic material in Examples and Comparative Examples are as illustrated in Table 1 below. In Tables 1 and 2, “BG” represents band gap energy (unit: eV). In Tables 1 and 2, a “thickness” represents the thickness of each layer. LiF can be exemplified as a material constituting the electron injection layer, Bphene can be exemplified as a material constituting the electron transport layer, αNPD can be exemplified as a material constituting the hole transport layer, and HAT-CN can be exemplified as a material constituting the hole injection layer.

TABLE 1

| | Thickness | Material name | Mass ratio | BG (eV) |
|---|---|---|---|---|
| First light emitting layer | 10 nm | | | |
| Constituent material | | | | |
| Host | | MADN | 95 | 3.0 |
| Dopant | | TBP | 5 | 2.8 |
| Second light emitting layer | 10 nm | | | |
| Constituent material | | | | |
| Host | | Rubrene | 99 | 2.2 |
| Dopant | | DBP | 1 | 1.9 |
| Third light emitting layer | 10 nm | | | |
| Constituent material | | | | |
| Host | | MADN | 95 | 3.0 |
| Dopant | | TTPA | 5 | 2.4 |
| intermediate layer | 10 nm | | | |
| First organic material | | Refer to Table 2 | 50 | Refer to Table 2 |
| Second organic material | | MADN | 50 | 3.0 |

The first organic material is as illustrated in Table 2 below.

TABLE 2

| | Material name | BG(eV) | ΔBG | external quantum efficiency ratio |
|---|---|---|---|---|
| Example 1-A | PCZAC | 3.2 | 0.2 | 1.00 |
| Example 1-B | BBTC | 3.32 | 0.32 | 0.97 |
| Example 1-C | TCP | 3.5 | 0.5 | 0.92 |
| Comparative Example 1-d | αNPD | 3.1 | 0.1 | 0.71 |
| Comparative Example 1-e | TDP | 3.1 | 0.1 | 0.70 |
| Comparative Example 1-f | NPB | 3.0 | 0.0 | 0.57 |

Table 2 and FIG. 1B illustrate the results of obtaining the external quantum efficiency ratio of the light emitting element having the light emitting unit including the various materials described above. A horizontal axis in FIG. 1B indicates a value of ΔBG. Here, from Table 1, BGₘₐₓ = 3.0 eV. In FIG. 1B, “A” represents the result of Example 1-A, “B” represents the result of Example 1-B, “C” represents the result of Example 1-C, “d” represents the result of Comparative Example 1-d, “e” represents the result of Comparative Example 1-e, and “f” represents the result of Comparative Example 1-f.

From FIG. 1B, it is found that a high external quantum efficiency ratio can be obtained when the value of ΔBG is 0.2 eV or more.

From the above results, when the HOMO value of the first organic material 33e is HOMO_{HTM}, the HOMO value of one adjacent light emitting layer 33a is HOMO₁, and the HOMO value of the other adjacent light emitting layer 33b HOMO₂, from the viewpoint of suppressing generation of is hole accumulation,
   |HOMO₂| ≤ |HOMO_{HTM}| ≤ |HOMO₁| can satisfied preferably,
   |HOMO₂| < |HOMO_{HTM}| ≤ |HOMO₁| can be satisfied more preferably,
   |HOMO₂| < |HOMO_{HTM}| < |HOMO₁| can be satisfied,
and when the LUMO value of the second organic material 33f is LUMO_{ETM}, the LUMO value of one adjacent light emitting layer 33a is LUMO₁, and the LUMO value of the other adjacent light emitting layer 33b is LUMO₂, from the viewpoint of suppressing generation of electron accumulation,
   |LUMO_{ETM}| ≤ |LUMO1| can be satisfied,
   |LUMO_{ETM}| ≤ |LUMO₂| can be satisfied preferably,
   |LUMO_{ETM}| < |LUMO₁| can be satisfied, and
   |LUMO_{ETM}| < |LUMO₂| can be satisfied. In addition, from the viewpoint of suppressing generation of a charge accumulation between the intermediate layer and one light emitting layer and stabilizing driving of the light emitting element,
EM₁E ≤ EM_{ETM} can be satisfied, preferably,
EM₁E < EM_{ETM} can be satisfied Furthermore, from the viewpoint that the transfer of energy to the intermediate layer is suppressed,
preferably, M_{HTM} ≥ M_{ETM} can be satisfied.

As described above, since the light emitting element of Example 1 satisfies BG_{HTM}-BGₘₐₓ ≥ 0.2 eV, it is possible to prevent unnecessary energy transfer (energy loss) from the light emitting layer to the intermediate layer, and it is possible to achieve high efficiency of the light emitting element and long life of the display device.

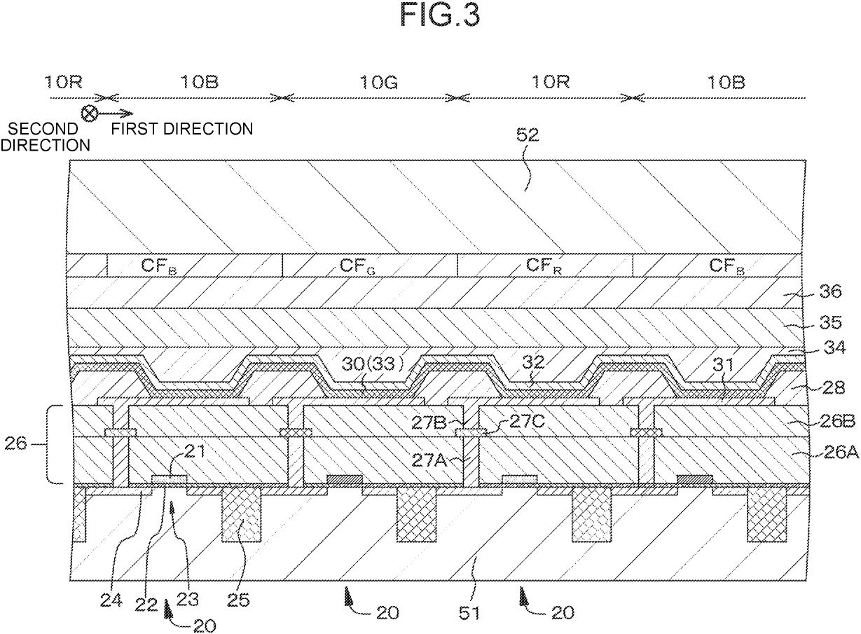

As illustrated in a schematic partial cross-sectional view of Modification-1 of the display device of Example 1 in FIG. 3, the color filter layer CF (CF_{R}, CF_{G}, CF_{B}) may be provided on an inner surface of the second substrate 52 facing the first substrate 51. The color filter layer CF and the flattening layer 35 are bonded to each other by the sealing resin layer 36 made of an acrylic adhesive. The flattening layer 35 may be omitted, and the color filter layer CF and the protective layer 34 may be bonded to each other by the sealing resin layer 36.

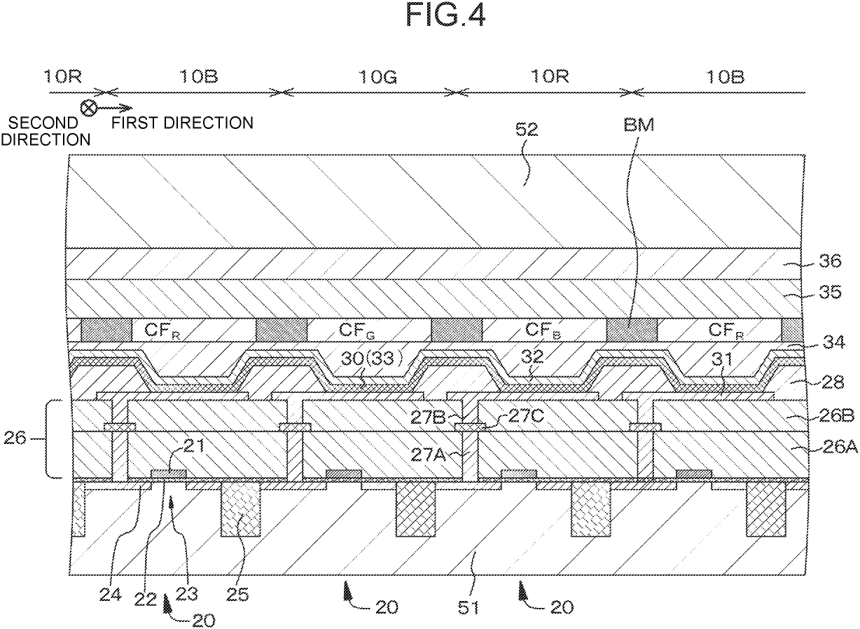

In addition, as illustrated in a schematic partial cross-sectional view of Modification-2 of the display device of Example 1 in FIG. 4, a light absorbing layer (black matrix layer) BM may be formed between the color filter layers CF of adjacent light emitting elements. The black matrix layer BM includes, for example, a black resin film (specifically, for example, a black polyimide-based resin) mixed with a black colorant and having an optical density of 1 or more.

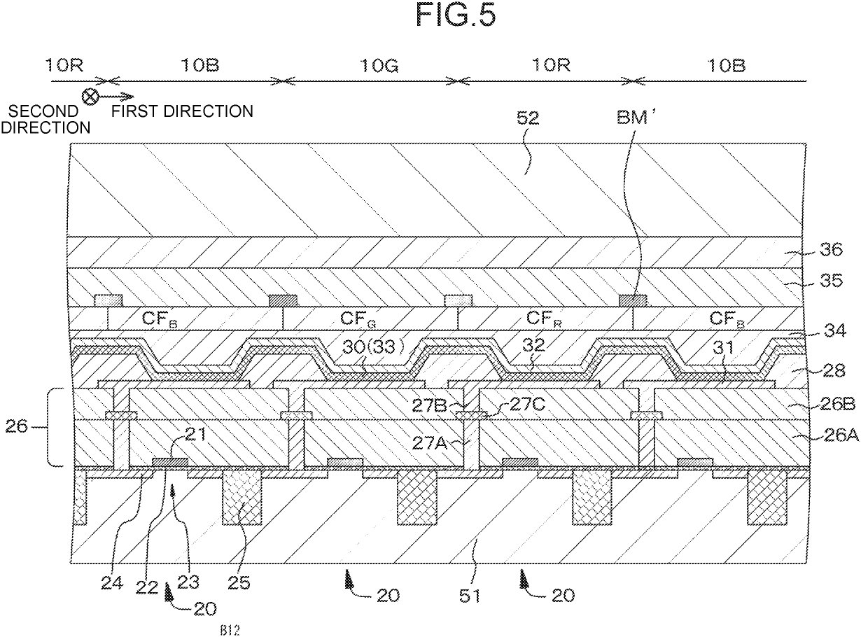

Furthermore, as illustrated in a schematic partial cross-sectional view of Modification-3 of the display device of Example 1 in FIG. 5, a light absorbing layer (black matrix layer) BM′ may be formed above between color filter layers CF of adjacent light emitting elements. Furthermore, Modification-2 and Modification-3 can be combined, and various modifications or combinations of modifications can be applied to other examples.

The flattening layer may have a function as a color filter layer. That is, the flattening layer having such a function may be formed of a known color resist material. When the flattening layer also functions as a color filter layer as described above, the organic layer and the flattening layer can be arranged close to each other, and color mixing can be effectively prevented even when the angle of light emitted from the light emitting element is widened, and the viewing angle characteristics are improved.

### Example 2

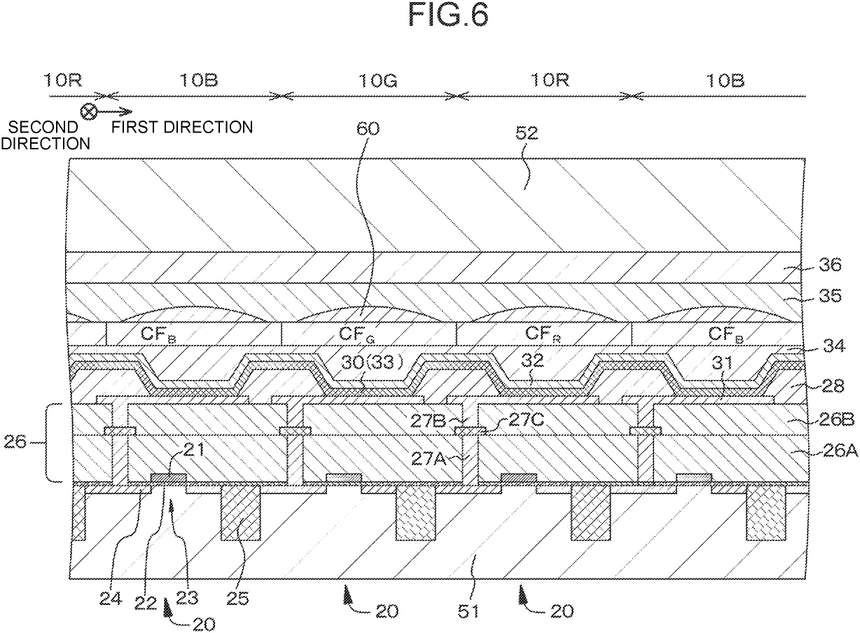

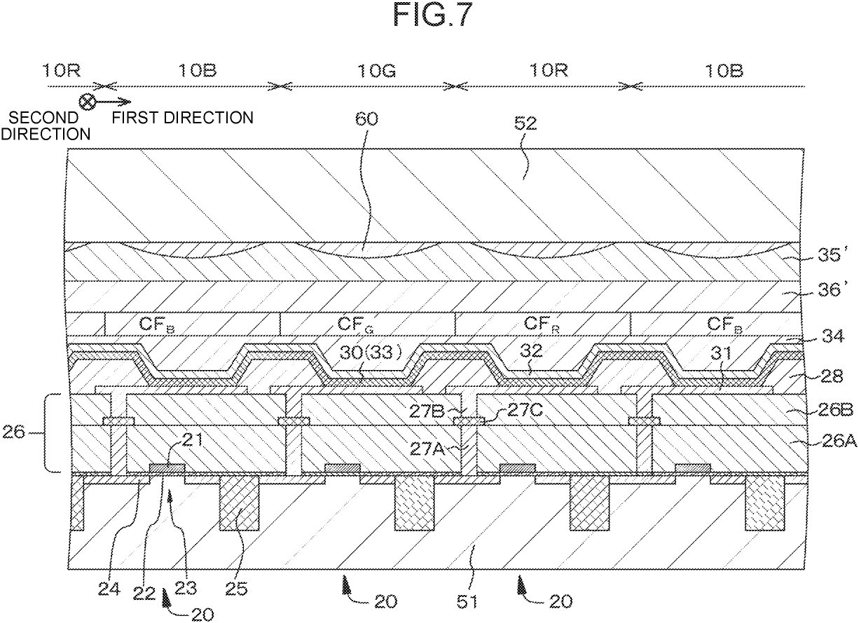

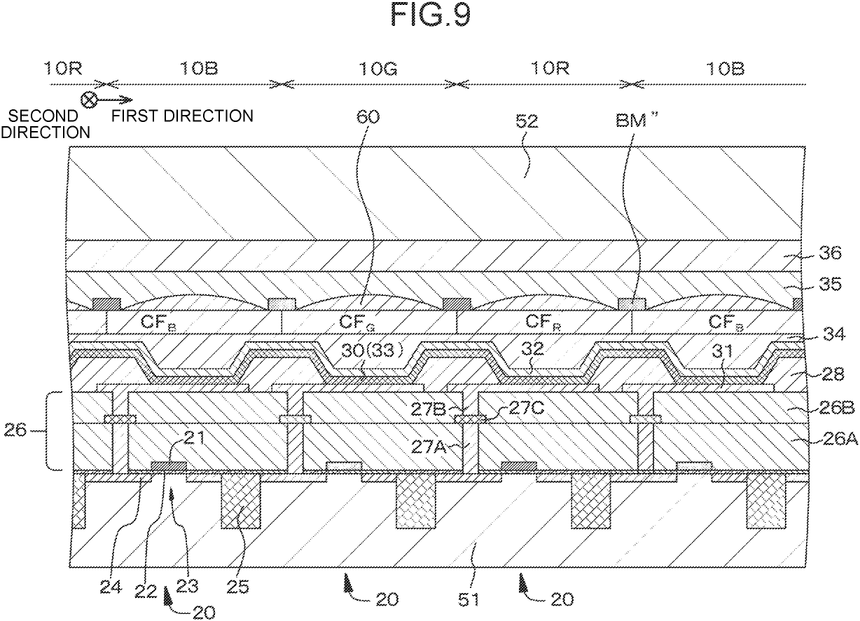

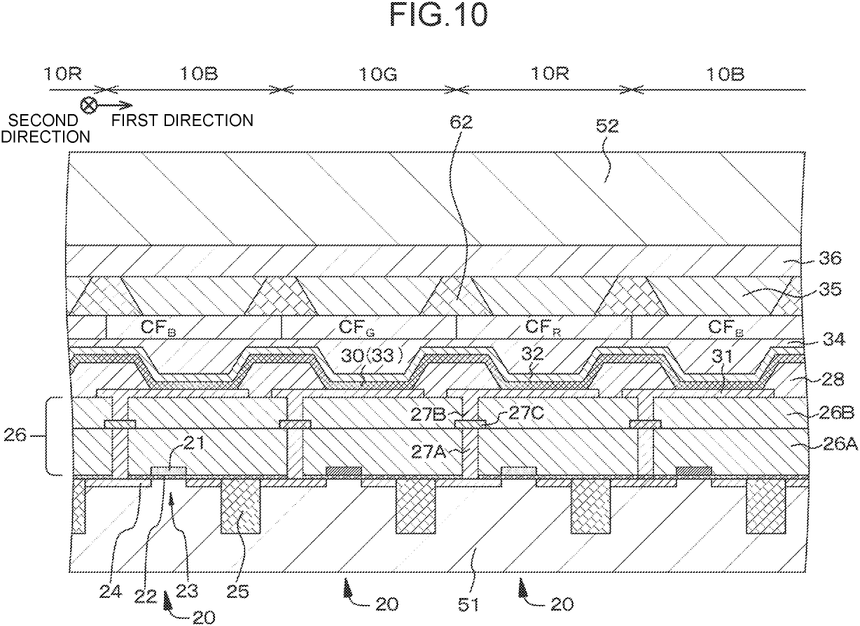

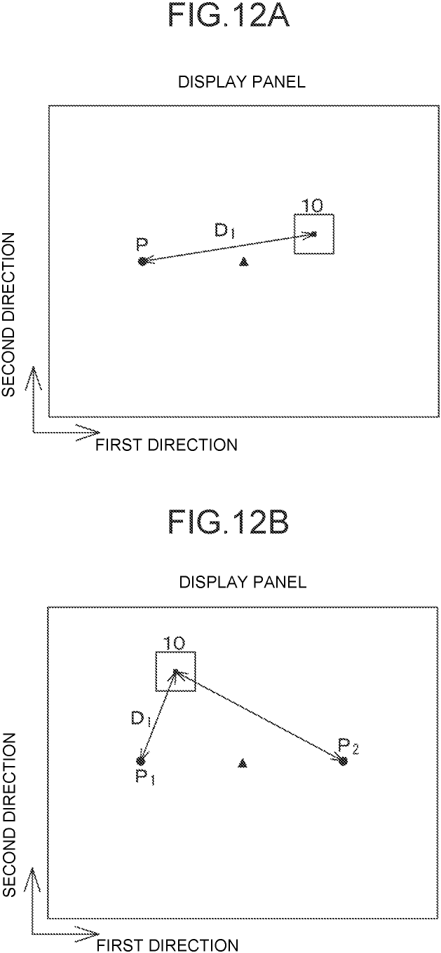

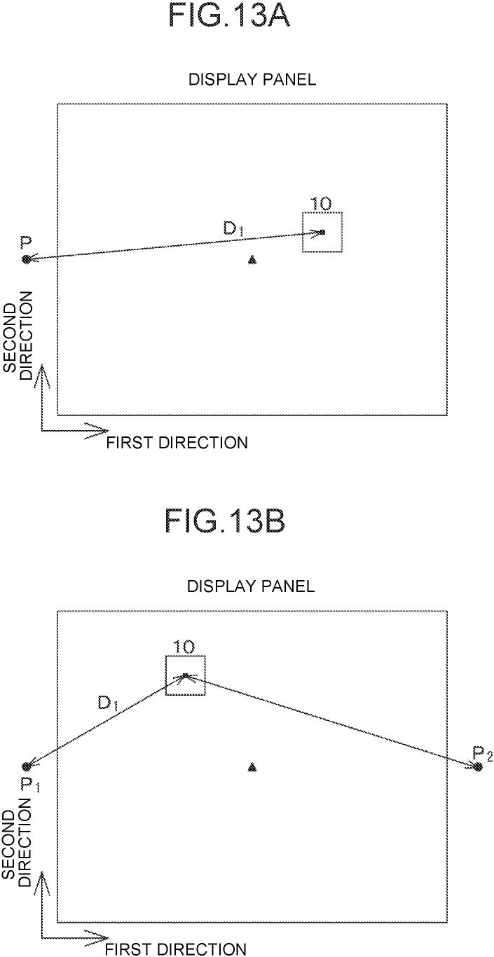

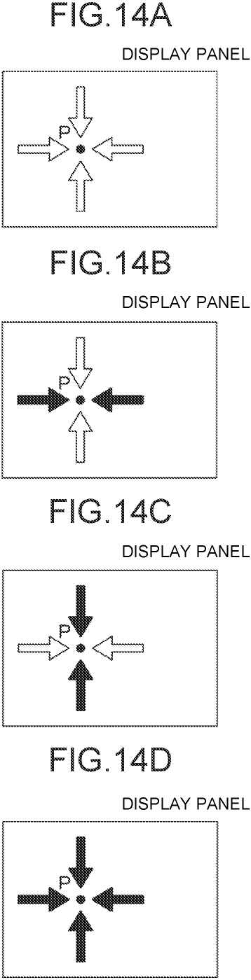

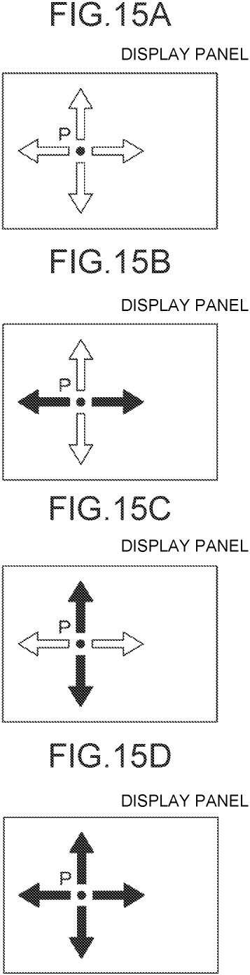

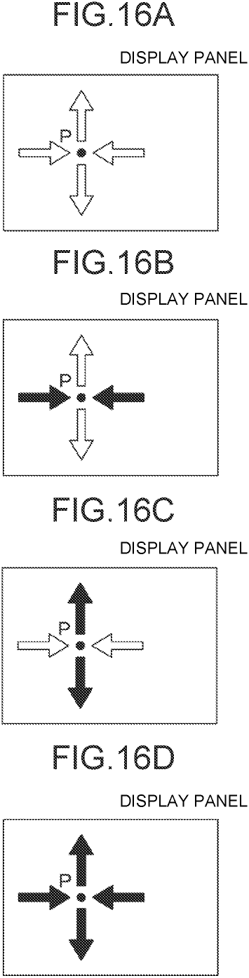

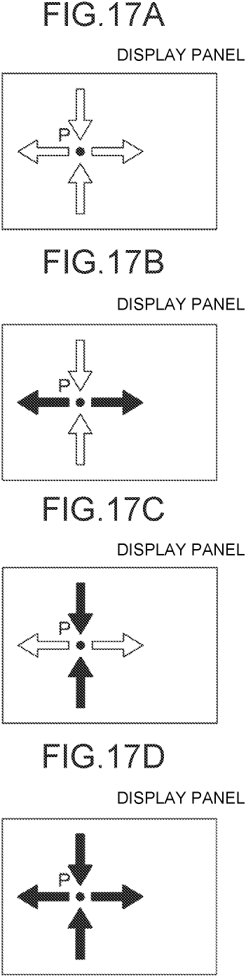

Example 2 is a modification of Example 1. The display device of Example 2 includes an optical path control unit through which the light emitted from the light emitting unit passes. FIG. 6, FIG. 7, FIG. 3, FIG. 9, and FIG. 10 are schematic partial cross-sectional views of a display device and a light emitting element of Example 2. in addition, schematic diagrams illustrating a positional relationship between the light emitting element and the reference point in the display device of Example 2 are illustrated in FIGS. 12A and 12B and FIGS. 13A and 13B, and changes in D_{0-X} with respect to changes in D_{1-X} and changes in D_{0-Y} with respect to changes in D_{1-Y} are schematically illustrated in FIGS. 14A, 14B, 14C, and 14D, FIGS. 15A, 15B, 15C, and 15D, FIGS. 16A, 16B, 16C, and 16D, and FIGS. 17A, 17B, 17C, and 17D.

That is, in the display device or the light emitting element of the present disclosure, an optical path control unit through which the light emitted from the light emitting unit passes may be provided. The optical path control unit is provided on or above the light emitting unit. Specifically, a mode in which the optical path control unit is formed on or above the protective layer, a mode in which the wavelength selection unit is formed on or above the protective layer and the optical path control unit is formed on or above the wavelength selection unit, or a mode in which the optical path control unit is formed on or above the protective layer and the wavelength selection unit is formed on or above optical path control unit can be adopted.The optical path control unit is provided on the first substrate side or the second substrate side. The mode in which the optical path control unit is formed on the wavelength selection unit includes a mode in which a base layer for flattening the unevenness of the wavelength selection unit is formed between the wavelength selection unit and the optical path control unit.

For example, the optical path control unit may be configured by a lens member, and may be configured by a hemispherical shape or a part of a sphere, or may be configured by a shape suitable for functioning as a lens in a broad sense. Specifically, the optical path control unit may include a convex lens member (on-chip micro-convex lens) or a concave lens member (on-chip micro-concave lens) . In the following description, the convex lens member and the concave lens member may be collectively referred to as a “lens member”. The lens member may be a spherical lens or an aspherical lens. Further, the convex lens member can be formed of a plano-convex lens, and the concave lens member can be formed of a plano-concave lens. Furthermore, the lens member may be a refractive lens or a diffractive lens.

Alternatively, a rectangular parallelepiped having a square or rectangular bottom surface is assumed, four side surfaces and one top surface of the rectangular parallelepiped have a convex shape, a portion of a ridge where the side surfaces intersect each other is rounded, and a portion of a ridge where the top surfaces intersect each other is also rounded, and the lens member can have a rounded three-dimensional shape as a whole.

The lens member can be obtained by melt-flowing or etching back a transparent resin material constituting the lens member, can be obtained by a combination of a photolithography technique using a gray tone mask and an etching method, or can be obtained by a method of forming a transparent resin material into a lens shape on the basis of a nanoimprint method. Examples of the material constituting the lens member (microlens) include a high refractive resin material (for a convex lens), a high refractive inorganic film (for a convex lens), a low refractive resin material (for a concave lens), and a low refractive inorganic film (for a concave lens). The lens member (on-chip microlens) as the optical path control unit can be made of, for example, a transparent resin material such as an acrylic resin, an epoxy resin, a polycarbonate resin, or a polyimide resin, or a transparent inorganic material such as SiO₂.

Alternatively, the optical path control unit may include a light emission direction control member having a rectangular or isosceles trapezoidal cross-sectional shape when cut along a virtual plane (vertical virtual plane) including the thickness direction. In other words, the optical path control unit can be configured by a light emission direction control member in which the cross-sectional shape is constant or changes along the thickness direction.

In order to increase the light use efficiency of the entire display device, it is preferable to effectively collect the light at the outer edge portion of the light emitting element. However, in the hemispherical lens, although the effect of condensing the light near the center of the light emitting element to the front is large, the effect of condensing the light near the outer edge portion of the light emitting element may be small.

The side surface of the light emission direction control member is surrounded by a material or layer having a refractive index n₂ lower than a refractive index n₁ of the material constituting the light emission direction control member. Therefore, the light emission direction control member has a function as a kind of lens, and can effectively enhance a light condensing effect in the vicinity of an outer edge portion of the light emission direction control member. When a light beam is incident on the side surface of the light emission direction control member in the case of geometrical optics, an incident angle and a reflection angle become equal, and thus, it is difficult to improve the extraction in a front direction. However, considering a wave analysis (FDTD), the light extraction efficiency in the vicinity of the outer edge portion of the light emission direction control member is improved. Therefore, the light in the vicinity of the outer edge portion of the light emitting element can be effectively condensed, and as a result, the light extraction efficiency in the front direction of the entire light emitting element is improved. Therefore, high light emission efficiency of the display device can be achieved. That is, it is possible to realize high luminance and low power consumption of the display device. In addition, since the light emission direction control member has a flat plate shape, the light emission direction control member is easily formed, and the manufacturing process can be simplified.

Specifically, examples of the three-dimensional shape of the light emission direction control member can include a columnar shape, an elliptical columnar shape, an oval columnar shape, a cylindrical shape, a prismatic shape (hexagonal prisms, octagonal prisms, prismatic prisms with rounded ridges), a truncated conical shape, and a truncated pyramid shape (including a truncated pyramid shape with rounded ridges). The prism shape and the truncated pyramid shape include a regular prism shape and a regular truncated pyramid shape. The portion of the ridge where the side surface and the top surface of the light emission direction control member intersect may be rounded. The bottom surface of the truncated pyramid may be located on the first substrate side or on the second electrode side. Alternatively, specific examples of the planar shape of the light emission direction control member include a circle, an ellipse, and an oval, and a polygon including a triangle, a quadrangle, a hexagon, and an octagon. The polygon includes a regular polygon (including a regular polygon such as a rectangle or a regular hexagon (honeycomb shape) ). The light emission direction control member can be made of, for example, a transparent resin material such as an acrylic resin, an epoxy resin, a polycarbonate resin, or a polyimide resin, or a transparent inorganic material such as SiO₂.

The cross-sectional shape of the side surface of the light emission direction control member in the thickness direction may be linear, convexly curved, or concavely curved. That is, the side surface of the prism or the truncated pyramid may be flat, curved convexly, or curved concavely.

A light emission direction control member extending portion having a smaller thickness than the light emission direction control member may be formed between the adjacent light emission direction control member and light emission direction control member.

The top surface of the light emission direction control member may be flat, may have an upward convex shape, or may have a concave shape, but from the viewpoint of improving the luminance in the front direction of the image display region (display panel) of the display device, the top surface of the light emission direction control member is preferably flat. The light emission direction control member can be obtained by, for example, a combination of a photolithography technique and an etching method, or can be formed on the basis of a nano-printing method.

The size of the planar shape of the light emission direction control member may be changed depending on the light emitting element. For example, in a case where one pixel includes three sub-pixels, the size of the planar shape of the light emission direction control member may have the same value in three sub-pixels constituting one pixel, may have the same value in two sub-pixels except for one sub-pixel, or may have different values in three sub-pixels. In addition, the refractive index of the material constituting the light emission direction control member may be changed depending on the light emitting element. For example, in a case where one pixel includes three sub-pixels, the refractive indexes of the materials constituting the light emission direction control member may have the same value in the three sub-pixels constituting one pixel, may have the same value in the two sub-pixels except for one sub-pixel, or may have different values in the three sub-pixels.

The planar shape of the light emission direction control member is preferably similar to the light emitting region, or the light emitting region is preferably included in an orthogonal projection image of the light emission direction control member. The orthogonal projection image is an orthogonal projection image when projected onto the first substrate, and the same applies hereinafter.

The side surface of the light emission direction control member is preferably vertical or substantially vertical. Specifically, examples of the inclination angle of the side surface of the light emission direction control member can include 80 degrees to 100 degrees, preferably 81.8 degrees or more and 98.2 degrees or less, more preferably 84.0 degrees or more and 96.0 degrees or less, still more preferably 86.0 degrees or more and 94.0 degrees or less, particularly preferably 88.0 degrees or more and 92.0 degrees or less, and most preferably 90 degrees.

In addition, an average height of the light emission direction control member may be 1.5 µm or more and 2.5 µm or less, and this can effectively enhance the light condensing effect in the vicinity of the outer edge portion of the light emission direction control member. The height of the light emission direction control member may be changed depending on the light emitting element. For example, in a case where one pixel includes three sub-pixels, the height of the light emission direction control member may have the same value in three sub-pixels constituting one pixel, may have the same value in two sub-pixels except for one sub-pixel, or may have different values in three sub-pixels.

The shortest distance between the side surfaces of the adjacent light emission direction control members may be 0.4 µm or more and 1.2 µm or less, preferably 0.6 µm or more and 1.2 µm or less, more preferably 0.8 µm or more and 1.2 µm or less, and still more preferably 0.8 µm or more and 1.0 µm or less. By defining the minimum value of the shortest distance between the side surfaces of the adjacent light emission direction control members to be 0.4 µm, the shortest distance between the adjacent light emission direction control members can be set to be about the same as the lower limit value of the wavelength band of the visible light, and thus, it is possible to suppress the functional degradation of the material or layer surrounding the light emission direction control member, and as a result, it is possible to effectively enhance the light condensing effect in the vicinity of the outer edge portion of the light emission direction control member. Meanwhile, by defining the maximum value of the shortest distance between the side surfaces of the adjacent light emission direction control members to be 1.2 µm, the size of the light emission direction control members can be reduced, and as a result, the light condensing effect in the vicinity of the outer edge portion of the light emission direction control members can be effectively enhanced.

The distance between the centers of the adjacent light emission direction control members is preferably 1 µm or more and 10 µm or less, and by setting the distance to 10 µm or less, the wave property of the light is remarkably exhibited, and thus, a high light condensing effect can be imparted to the light emission direction control members.

The maximum distance (maximum distance in the height direction) from the light emitting unit to the bottom surface of the light emission direction control member is desirably more than 0.35 µm and 7 µm or less, preferably 1.3 µm or more and 7 µm or less, more preferably 2.8 µm or more and 7 µm or less, and still more preferably 3.8 µm or more and 7 µm or less. By defining that the maximum distance from the light emitting unit to the light emission direction control member exceeds 0.35 µm, the light condensing effect in the vicinity of the outer edge portion of the light emission direction control member can be effectively enhanced. Meanwhile, by defining that the maximum distance from the light emitting unit to the light emission direction control member is 7 µm or less, it is possible to suppress deterioration in viewing angle characteristics.

The number of light emission direction control members for one pixel is essentially arbitrary, and may be one or more. For example, in a case where one pixel includes a plurality of sub-pixels, one light emission direction control member may be provided corresponding to one sub-pixel, one light emission direction control member may be provided corresponding to a plurality of sub-pixels, or a plurality of light emission direction control members may be provided corresponding to one sub-pixel. In a case where p × q light emission direction control members are provided corresponding to one sub-pixel, the values of p and q may be 10 or less, 5 or less, or 3 or less.

Alternatively, the optical path control unit may include the light reflecting member. Examples of the light reflecting member can include a simple substance or an alloy of metal such as aluminum (Al) or silver (Ag), and a dielectric multilayer film. In the light emitting element and the like of the present disclosure, examples of the light reflecting member can include a material having a refractive index such that light from the light emitting unit is totally reflected by the light reflecting member when passing through the flattening layer and a covering layer and colliding with the light reflecting member. Specifically, the light reflecting member may fill a space between the covering layer and the covering layer, for example. The light reflecting member preferably has a forward tapered shape (a shape expanding from the light incident surface side toward a light emitting surface side). The cross-section of the forward tapered inclined surface when the light reflecting member is cut along a virtual plane (vertical virtual plane) including an axis of the light reflecting member may be formed of a curve or a line segment.

The orthogonal projection image of the optical path control unit may be in a form that matches the orthogonal projection image of the wavelength selection unit, or may be in a form included in the orthogonal projection image of the wavelength selection unit. By adopting the latter configuration, the occurrence of color mixing between adjacent light emitting elements can be reliably suppressed.

In each light emitting element, when a distance (offset amount) between a normal line LN passing through the center of the light emitting unit and the normal line LN′ passing through the center of the optical path control unit is D₀, the value of the distance (offset amount) D₀ may not be 0 in at least a part of the light emitting elements constituting the display device. Furthermore, in the display device, the reference point (reference region) P is assumed, and the distance D₀ can depend on the distance D₁ from the reference point (reference region) P to the normal line LN passing through the center of the light emitting unit. The reference point (reference region) may include a certain extent of spread. Here, the various normal lines are perpendicular lines to the light exit surface of the display device. The center of the light emitting unit refers to an area centroid point of a region where the first electrode and the organic layer are in contact with each other.

For example, in a case where one pixel includes three sub-pixels, the value of D₀ may be the same value in three sub-pixels constituting one pixel, may be the same value in two sub-pixels except one sub-pixel, or may be different values in three sub-pixels.

Whether the light (image) emitted from the entire display device is a focusing system or a diverging system depends on the specification of the display device, and also depends on how much viewing angle dependency and wide viewing angle characteristics are required for the display device.

As illustrated in a schematic partial cross-sectional view of a display device of Example 2 in FIG. 6, a lens member (on-chip microlens) 60 which is an optical path control unit through which light emitted from a light emitting unit 30 passes is provided above the light emitting unit 30, specifically, on a color filter layer CF provided on a protective layer 34. The protective layer 34 and the lens member 60 are covered with a flattening layer 35, and the flattening layer 35 and the second substrate 52 are bonded to each other with a resin layer (sealing resin layer) 36 interposed therebetween, for example.

The lens member 60 can be manufactured, for example, by the following method. That is, a lens member forming layer for forming the lens member 60 is formed on the color filter layer CF, and a resist material layer is formed thereon. Then, the resist material layer is patterned and further subjected to heat treatment to form the resist material layer into a lens member shape. Next, the resist material layer and the lens member forming layer are etched back to transfer the shape formed in the resist material layer to the lens member forming layer. In this way, the lens member 60 can be obtained.

Alternatively, as Modification-1 of the display device of Example 2, as illustrated in a schematic partial cross-sectional view in FIG. 7, the lens member 60 is provided on a surface of the second substrate 52 facing the first substrate 51, the lens member 60 and the second substrate 52 are covered with the flattening layer 35′, and the flattening layer 35′ and the color filter layer CF are bonded via, for example, a resin layer (sealing resin layer) 36′.

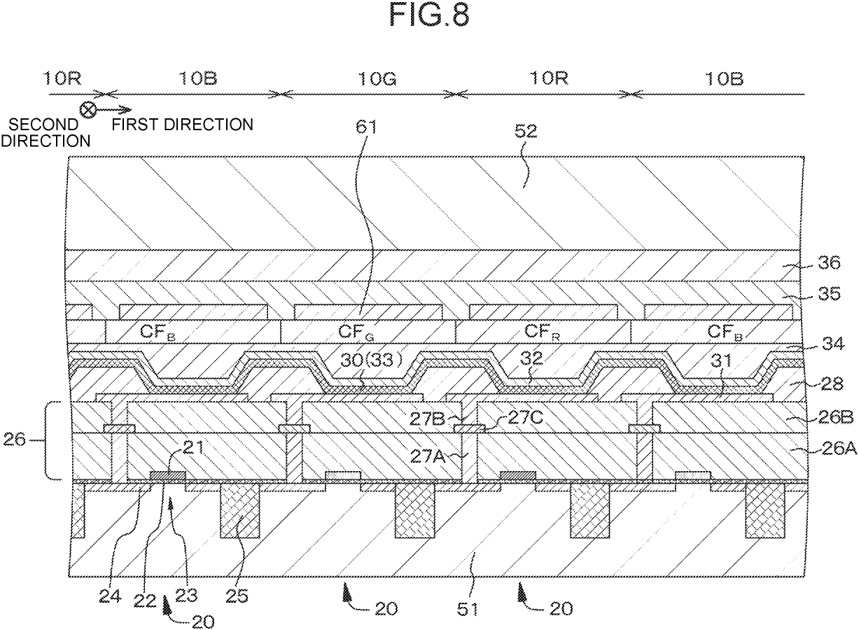

Alternatively, as Modification-2 of the display device of Example 2, as illustrated in a schematic partial cross-sectional view in FIG. 8, the light emission direction control member 61 as the optical path control. unit is provided above the light emitting unit 30, specifically, on the color filter layer CF provided on the protective layer 34. The protective layer 34 and the light emission di re ct ion control member 61 are covered with a flattening layer 35, and the flattening layer 35 and the second substrate 52 are joined to each other with a resin layer (sealing resin layer) 36 interposed therebetween, for example. The cross-sectional shape of the light emission direction control member 61 when the light emission direction control member is cut along a virtual plane (vertical virtual plane) including the thickness direction of the light emission direction control member 61 is rectangular. The three-dimensional shape of the light emission direction control member 61 is, for example, a columnar shape. Assuming that the refractive index of the material constituting the light emission direction control member 61 is n₁ and the refractive index of the material constituting the flattening layer 35 is n₂(< n₁), since the light emission direction control member 61 is surrounded by the flattening layer 35, the light emission direction control member 61 has a function as a kind of lens, and furthermore, it is possible to effectively enhance the light condensing effect in the vicinity of the outer edge portion of the light emission direction control member 61. In addition, since the light emission direction control member 61 has a flat plate shape, it is easy to form the light emission direction control member, and the manufacturing process can be simplified. The light emission direction control member 61 may be surrounded by a material different from the material constituting the flattening layer 35 as long as the refractive index condition (n₂ < n₁) is satisfied. Alternatively, the light emission direction control member 61 may be surrounded by, for example, an air layer or a decompression layer (vacuum layer).

In addition, as Modification-3 of the display device of Example 2, as illustrated in a schematic partial cross-sectional view in FIG. 9, a light absorbing layer black matrix layer) BM” may be formed between the optical path control units 60 and 61 of the adjacent light emitting elements, and thus, occurrence of color mixture between the adjacent light emitting elements can be reliably suppressed.

As illustrated in a schematic partial cross-sectional view as Modification-4 of Example 2 in FIG. 10, the optical path control unit may include a light reflecting member 62. Examples of the light reflecting member 62 include a simple substance or an alloy of metal such as aluminum (Al) or silver (Ag) , and a dielectric multilayer film. Alternatively, examples of the light reflecting member 62 include a material (for example, n₃ = 1.52 SiO₂) having a refractive index n₃ such that the light from the light emitting unit 30 is totally reflected by the light reflecting member 62 when passing through the covering layer 34 and the flattening layer 35 and colliding with the light reflecting member 62. Specifically, the light reflecting member 62 constituting the optical path control unit fills a space between the flattening layer 35 and the flattening layer 35. The light reflecting member 62 has a forward tapered shape (a shape expanding from the light incident surface side toward the light emitting surface side). The cross-section of the forward tapered inclined surface when the light reflecting member 62 is cut along a virtual plane (vertical virtual plane) including the axis of the light reflecting member 62 may be configured by a curve or may be configured by a line segment as illustrated in FIG. 10.

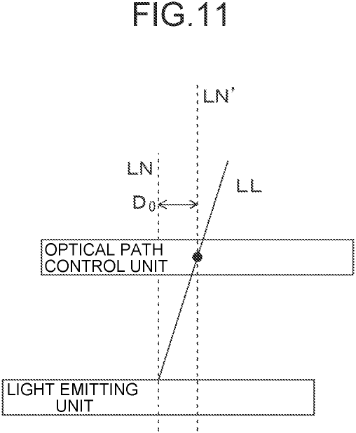

As illustrated in the conceptual diagram in FIG. 11, in the display device of Example 2, as described above, when the distance (offset amount) between the normal line LN passing through the center of the light emitting unit 30 and the normal line LN′ passing through the centers of the optical path control units 60 and 61 is D₀, the value of the distance (offset amount) D₀ can be set to not 0 in at least a part of the light emitting element 10 constituting the display device. A straight line LL is a straight line connecting the center of the light emitting unit 30 and the centers of the optical path control units 60 and 61. The center of the light emitting unit 30 refers to an area centroid point of a region where the first electrode 31 and the organic layer 33 are in contact with each other. In the following description, the optical path control units 60 and 61 may be collectively expressed by the optical path control unit 60.

Then, the reference point (reference region) P is assumed, and the distance D₀ can depend on the distance D₁ from the reference point (reference region) P to the normal line LN passing through the center of the light emitting unit 30. The reference point (reference region) may include a certain extent of spread. Here, the various normal lines are perpendicular lines to the light exit surface of the display device.

In the display panel constituting the display device of Example 2 including the preferable form, the reference point P can be assumed in the display panel, and in this case, the reference point P can be configured not to be located in the center region of the display panel, or the reference point P can be configured to be located in the center region of the display panel. Furthermore, in these cases, one reference point P can be assumed, or a plurality of reference points P can be assumed. In these cases, the value of the distance D₀ may be 0 in some light emitting elements, and the value of the distance D₀ may not be 0 in the remaining light emitting elements.

Alternatively, in the display device of Example 2 including the preferable mode, when one reference point P is assumed, the reference point P may not be included in the center region of the display panel, or the reference point P may be included in the center region of the display panel. When the plurality of reference points P are assumed, at least one reference point P may not be included in the center region of the display panel.

Alternatively, the reference point P can be assumed outside (outside) the display panel. In this case, one reference point P can be assumed, or a plurality of reference points P can be assumed. In these cases, the value of the distance D₀ can be configured not to be 0 in all the light emitting elements.

Furthermore, in the display device of Example 2 including the preferable forms and configurations described above, the light emitted from each light emitting element and passing through the optical path control unit 60 can be converged (condensed) to a certain region of the space outside the display device. Alternatively, the light emitted from each light emitting element and passing through the optical path control unit 60 can be diverged in the space outside the display device. Alternatively, the light emitted from each light emitting element and passing through the optical path control unit 60 can be parallel light.

Furthermore, in the display device of Example 2, the value of the distance (offset amount) D₀ may be different according to the position where the light emitting element occupies the display panel. Specifically,
a reference point P is set, and
the plurality of light emitting elements are arranged in a first direction and a second direction different from the first direction, and
when the distance from the reference point P to the normal line LN passing through the center of the light emitting unit is D₁, values of the distance D₀ in the first direction and the second direction are D_{0-X} and D_{0-Y}, and values of the distance D₁ in the first direction and the second direction are D_{1-X} and D_{1-Y},
   D_{0-X} changes linearly with respect to the change of D₁₋_{X}, and D_{0-Y} changes linearly with respect to the change of D_{1-Y}, or
   D_{0-X} changes linearly with respect to the change of D₁₋_{X}, and D_{0-Y} changes nonlinearly with respect to the change of D_{1-Y}, or
   D_{0-X} changes nonlinearly with respect to the change of D_{1-X}, and D_{0-Y} changes linearly with respect to the change of D_{1-Y}, or
   D_{0-X} changes nonlinearly with respect to the change of D_{1-X}, and D_{0-Y} changes nonlinearly with respect to the change of D_{1-Y}.

Alternatively, the value of the distance D₀ can increase as the value of the distance D₁ increases. That is, in the display device of Example 2,
a reference point P is set, and
when the distance from the reference point P to the normal line LN passing through the center of the light emitting unit is D₁, the value of the distance D₀ can increase as the value of the distance D₁ increases.

Here, D_{0-X} changes linearly with respect to the change of D_{1-X}, and D_{0-Y} changes linearly with respect to the change of D_{1-Y} means that

$${\text{D}}_{0 - \text{X}} = {\text{k}}_{\text{X}} ⋅ {\text{D}}_{1 - \text{X}} \text{and}$$

$${\text{D}}_{0 - \text{Y}} = {\text{k}}_{\text{Y}} ⋅ {\text{D}}_{1 - \text{Y}}$$

is established. Here, k_{X} and k_{Y} are constants. That is, D_{0-X} and D_{0-Y} change on the basis of a linear function. Meanwhile, D_{0-X} changes nonlinearly with respect to the change of D_{1-X}, and D_{0-Y} changes linearly with respect to the change of D_{1-Y} means that

$${\text{D}}_{0 - \text{X}} = {\text{f}}_{\text{X}} \left({\text{D}}_{\text{1} - \text{X}}\right) \text{and}$$

$${\text{D}}_{0 - \text{Y}} = {\text{f}}_{\text{Y}} \left({\text{D}}_{1 - \text{Y}}\right)$$

is established. Here, f_{X} and f_{Y} are functions that are not linear functions (for example, a quadratic function).

Alternatively, the change in D_{0-X} with respect to the change in D_{1-X} and the change in D_{0-Y} with respect to the change in D_{1-Y} can also be stepwise changes. Then, in this case, when the stepwise change is viewed as a whole, a form in which the change changes linearly can be adopted, or a form in which the change changes nonlinearly can be adopted. Furthermore, when the display panel is divided into the M × N regions, in one region, the change of D_{0-X} with respect to the change of D_{1-X} and the change of D_{0-Y} with respect to the change of D_{1-Y} may be unchanged or constant. The number of light emitting elements in one region may be, but is not limited to, 10 × 10.

In the display device of Example 2 in which conceptual diagrams are illustrated in FIGS. 12A and 12B, the reference point P is assumed in the display device. That is, the orthogonal projection image of the reference point P is included in the image display region (display panel) of the display device, but the reference point P is not located in the center region of the display device (display region of display device, display panel). In FIGS. 12A, 12B, 13A, and 13B, the center region is indicated by a black triangle mark, the light emitting element is indicated by a square mark, and the center of the light emitting unit 30 is indicated by a black square mark. Then, one reference point P is assumed. The positional relationship between the light emitting element 10 and the reference point P is schematically illustrated in FIGS. 12A and 12B, and the reference point P is indicated by a black circle. One reference point P is assumed in FIG. 12A, and a plurality of reference points P (FIG. 12B illustrates two reference points P₁ and P₂₎ are assumed in FIG. 12B. Since the reference point P may include a certain extent of spread, the value of the distance Dₒ is 0 in some light emitting elements (specifically, one or a plurality of light emitting elements included in the orthogonal projection image of the reference point P) , and the value of the distance D₀ is not 0 in the remaining light emitting elements. The value of the (offset amount) D₀ varies depending on the position occupied by the light emitting element in the display panel.

In the display device of Example 2, the light emitted from each light emitting element 10 and passing through the optical path control unit 60 converges (converges) on a certain region in a space outside the display device. Alternatively, the light emitted from each light emitting element 10 and passing through the optical path control unit 60 diverges in a space outside the display device. Alternatively, the light emitted from each light emitting element 10 and passing through the optical path control, unit 60 is parallel light. Whether the light passing through the optical path control unit 60 is convergent light, divergent light, or parallel light is based on specifications required for the display device. Then, the power or the like of the optical path control unit 60 may be designed on the basis of this specification, in a case where the light having passed through the optical path control unit 60 is convergent light, the position of the space in which the image emitted from the display device is formed may or may not be on the normal line of the reference point P, and depends on the specifications required for the display device. An optical system through which the image emitted from the display device passes may be arranged in order to control a display dimension, a display position, and the like of the image emitted from the display device. Which optical system is disposed depends on specifications required for the display device, and for example, an imaging lens system can be exemplified.

In the display device of Example 2, the reference point P is set, and the plurality of light emitting elements 10 are arrayed in the first direction (specifically, in the X direction,) and the second direction (specifically, in the Y direction,) different from the first direction. When the distance from the reference point P to the normal line LN passing through the center of the light emitting unit 30 is defined as D₁, the values of the distance D₀ in the first direction (X direction) and the second direction (Y direction) are defined as D₀₋ₓ and D_{0-y}, and the values of the distance D₁ in the first direction (X direction) and the second direction (Y direction) are defined as D₁₋ₓ and D_{1-y},
[A] D₀₋ₓ may be designed to change linearly with respect to the change of D₁-ₓ, an d D_{0-y} may be designed to change linearly with respect to the change of D_{1-Y,}
[B] D₀₋ₓ may be designed to change linearly with respect to the change of D₁-ₓ, an d D_{0-y} may be designed to change nonlinearly with respect to the change of D_{1-y},
[C] D₀₋ₓ may be designed to change nonlinearly with respect to the change of D₁-ₓ, and D_{0-Y} may be designed to change linearly with respect to the change of D_{1-y}, and
[D] D₀₋ₓ may be designed to change nonlinearly with respect to the change of D₁-ₓ, and D_{0-Y} may be designed to change nonlinearly with respect to the change of D_{1-Y}.

FIGS. 14A, 14B, 14C, 14D, 15A, 15B, 15C, 15D, 16A, 16B, 16C, 16D, 17A, 17B, 17C, and 17D schematically illustrate the change in D₀₋ₓ with respect to the change in D_{1-X} and the change in D_{0-Y} with respect to the change in D₁₋_{Y}. In these drawings, outlined arrows indicate linear changes and black arrows indicate non-linear changes. In addition, in a case where the arrow is directed to the outside of the display panel, it indicates that the light passing through the optical path control unit 60 is divergent light, and in a case where the arrow is directed to the inside of the display panel, it indicates that the light passing through the optical path control unit 60 is convergent light or parallel light.

Alternatively, when the reference point P is set and the distance from the reference point P to the normal line LN passing through the center of the light emitting unit 30 is D₁, the value of the distance D₀ may be designed. to increase as the value of the distance D₁ increases.

That is, the changes in D₀₋ₓ and D_{0-Y} depending on the changes in D₁₋ₓ and D_{1-Y} may be determined based on the specifications required for the display device.

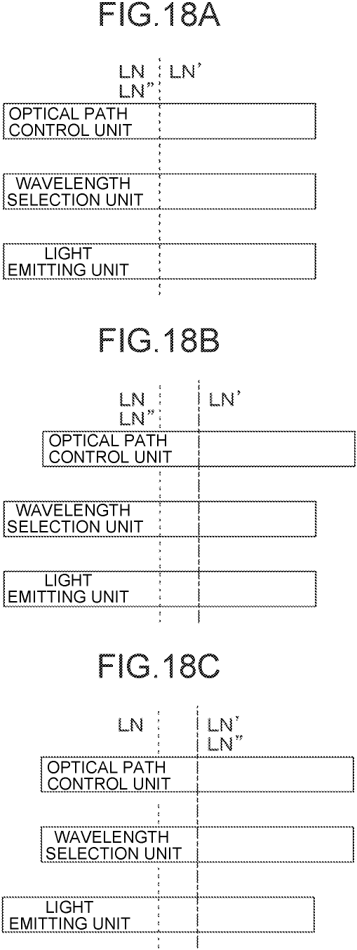

The orthogonal projection image of the optical path control unit 60 is included in the orthogonal projection images of the color filter layers CF_{R}, CF_{G}, and CF_{B}. These orthogonal projection images are orthogonal projection images for the first substrate as described above. The outer shapes of the light emitting unit 30, the color filter layer CF, and the optical path control unit 60 are circular for the sake of convenience, but are not limited to such shapes. Furthermore, in the light emitting element 10 in which the value of the distance D₀ is not 0, for example, as illustrated in FIG. 18B, the normal line LN” passing through the centers of the color filter layers CF_{R}, CF_{G}, and CF_{B} coincides with the normal line LN passing through the center of the light emitting unit.

In a preferred mode of the display device of Example 2, when the distance between the normal line LN passing through the center of the light emitting unit and the normal line LN’ passing through the center of the optical path control unit is D₀, the value of the distance D₀ is not 0 in at least some of the light emitting elements constituting the display device, and thus, it is possible to reliably and accurately control the traveling direction of the light emitted from the light emitting layer and passing through the optical path control unit depending on the position of the light emitting element in the display device. That is, it is possible to reliably and accurately control to which region in the external space the image from the display device is emitted in what state. In addition, by providing the optical path control unit, not only an increase in brightness (luminance) of an image emitted from the display device and prevention of color mixing between adjacent pixels can be achieved, but also light can be appropriately diverged according to a required viewing angle, and the life and luminance of the light emitting element and the display device can be extended and increased. Therefore, it is possible to achieve miniaturization, weight reduction, and high quality of the display device. In addition, applications to eyewear, augmented reality (AR) glasses, and EVR are remarkably expanded.

Alternatively, in a modification of the display device of Example 2, the reference point P is assumed outside the display device. FIGS. 13A and 13B schematically illustrate the positional relationship between the light emitting element 10 and the reference points P, P₁, and P₂. However, a configuration in which one reference point P is assumed can be adopted (refer to FIG. 13A), or a configuration in which a plurality of reference points P (FIG. 13B illustrates two reference points P₁ and P₂) are assumed can be adopted. With the center of the display panel as a symmetry point, the two reference points P₁ and P₂ are arranged in two-fold rotational symmetry. At this point, at least one reference point P is not included in the center region of the display panel. In the illustrated example, two reference points P₁ and P₂ are not included in the center region of the display panel. The value of the distance D₀ is 0 in some light emitting elements (specifically, one or a plurality of light emitting elements included in the reference point P), and the value of the distance D₀ is not 0 in the remaining light emitting elements. Regarding the distance D₁ from the reference point P to the normal line LN passing through the center of the light emitting unit 30, the distance between the reference point P closer to the normal line LN passing through the center of a certain light emitting unit 30 is defined as the distance D₁. Alternatively, the value of the distance D₀ is not 0 in all the light emitting elements. Regarding the distance D₁ from the reference point P to the normal line LN passing through the center of the light emitting unit 30, the distance between the reference point P closer to the normal line LN passing through the center of a certain light emitting unit 30 is defined as the distance D₁. In these cases, the light emitted from each light emitting element 10 and passing through the optical path control unit 60 converges (is condensed) or a certain region in the space outside the display device. Alternatively, the light emitted from each light emitting element 10 and passing through the optical path control unit 60 diverges in a space outside the display device.

Although one optical path control unit is provided for one light emitting unit, one optical path control unit may be shared by a plurality of light emitting elements in some cases. For example, the light emitting element may be arranged at each vertex of an equilateral triangle (a total of three light emitting elements are arranged), and one optical path control unit may be shared by these three light emitting elements, or a light emitting element may be arranged at each vertex of a rectangle (a total of four light emitting elements are arranged), and one optical path control unit may be shared by these four light emitting elements. Alternatively, a plurality of optical path control units may be provided for one light emitting unit.

### Example 3

In Example 3, an arrangement relationship of the light emitting unit, the wavelength selection unit, and the optical path control unit will be described. Here, in the light emitting element in which the value of the distance D₀ is not 0,
(a) the normal line LN” passing through the center of the wavelength selection unit can coincide with the normal line LN passing through the center of the light emitting unit,
(b) the normal line LN” passing through the center of the wavelength selection unit can coincide with the normal line LN′ passing through the center of the optical path control unit, and
(c) the normal line LN” passing through the center of the wavelength selection unit and the normal line LN passing through the center of the light emitting unit cannot coincide with each other, and the normal line LN” passing through the center of the wavelength selection unit and the normal line LN’ passing through the center of the optical path control unit cannot coincide with each other. By adopting (b) or the latter configuration of (c), the occurrence of color mixing between adjacent light emitting elements can be reliably suppressed. Here, the center of the wavelength selection unit refers to an area centroid point of a region occupied by the wavelength selection unit. Alternatively, when the planar shape of the wavelength selection unit is a circle, an ellipse, a square (including a square with rounded corners), a rectangle (including a rectangle with rounded corners), or a regular polygon (including a regular polygon with rounded corners), the center of these figures corresponds to the center of the wavelength selection unit, and when some of these figures are a cutout figure, the center of a figure complementing the cutout portion corresponds to the center of the wavelength selection unit. When these figures are connected figures, the connection portion is removed, and the center of a figure complementing the removed portion corresponds to the center of the wavelength selection unit. In addition, the center of the optical path control unit refers to an area centroid point of a region occupied by the optical path control unit. Alternatively, when the planar shape of the optical path control unit is a circle, an ellipse, a square (including a square with rounded corners), a rectangle (including a rectangle with rounded corners), or a regular polygon (including a regular polygon with rounded corners), the centers of these figures correspond to the center of the optical path control unit.

As illustrated in the conceptual diagram of FIG. 18A, the normal line LN passing through the center of the light emitting unit, the normal line LN” passing through the center of the wavelength selection unit, and a normal line LN′ passing through the center of the optical path control unit 60 may coincide with each other. That is, D₀ = d₀ = 0. As described above, d₀ is the distance (offset amount) between the normal line LN passing through the center of the light emitting unit and the normal line LN” passing through the center of the wavelength selection unit.

For example, in a case where one pixel includes three sub-pixels, the values of d₀ and D₀ may be the same value in three sub-pixels constituting one pixel, may be the same value in two sub-pixels except one sub-pixel, or may be different values in three sub-pixels.

In addition, as illustrated in the conceptual diagram of FIG. 18B, the normal line LN passing through the center of the light emitting unit, the normal line LN” passing through the center of the wavelength selection unit may coincide with each other, but and the normal line LN passing through the center of the light emitting unit, the normal line LN” passing through the center of the wavelength selection unit, and the normal line LN’ passing through the center of the optical path control unit 60 may not coincide with each other. That is, D₀ ≠ d₀ = 0.

Furthermore, as illustrated in the conceptual diagram of FIG. 18C, the normal line LN passing through the center of the light emitting unit, the normal line LN” passing through the center of the wavelength selection unit, and the normal line LN’ passing through the center of the optical path control unit 60 may not coincide with each other, and the normal line LN” passing through the center of the wavelength selection unit and the normal line LN’ passing through the center of the optical path control unit 60 may coincide with each other. That is, D₀ = d₀ > 0.

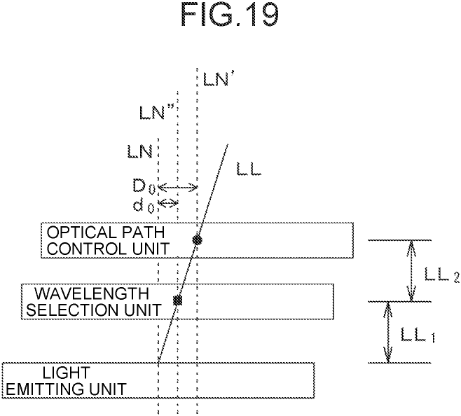

In addition, as illustrated in the conceptual diagram of FIG. 19, the normal line LN passing through the center of the light emitting unit, the normal line LN” passing through the center of the wavelength selection unit, and the normal line LN’ passing through the center of the optical path control unit 60 may not coincide with each other, and the normal line LN’ passing through the center of the optical path control unit 60 may not coincide with the normal line LN passing through the center of the light emitting unit and the normal line LN” passing through the center of the wavelength selection unit. Here, the center (indicated by a black square in FIG. 19) of the wavelength selection unit is preferably located on the straight line LL connecting the center of the light emitting unit and the center (indicated by a black circle in FIG. 19) of the optical path control unit 60. Specifically, when a distance from the center of the light emitting unit in the thickness direction to the center of the wavelength selection unit is LL₁, and a distance from the center of the wavelength selection unit in the thickness direction to the center of the optical path control unit 60 is LL₂,

$${\text{D}}_{0} > {\text{d}}_{0} > 0 \text{and}$$
considering manufacturing variations,
d₀: D₀ = LL₁: (LL₁ + LL₂) is preferably satisfied.

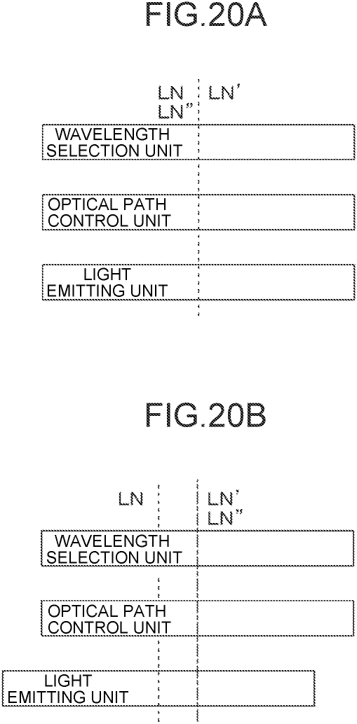

Alternatively, as illustrated in the conceptual diagram of FIG. 20A, the normal line LN passing through the center of the light emitting unit, the normal line LN” passing through the center of the wavelength selection unit, and the normal line LN’ passing through the center of the optical path control unit 60 may coincide with each other. That is, D₀ = d₀ = 0.

In addition, as illustrated in the conceptual diagram of FIG. 20B, the normal line LN passing through the center of the light emitting unit, the normal line LN” passing through the center of the wavelength selection unit, and the normal line LN’ passing through the center of the optical path control unit 60 may not coincide with each other, and the normal line LN” passing through the center of the wavelength selection unit and the normal line LN’ passing through the center of the optical path control unit 60 may coincide with each other. That is, D₀ = d₀ > 0.

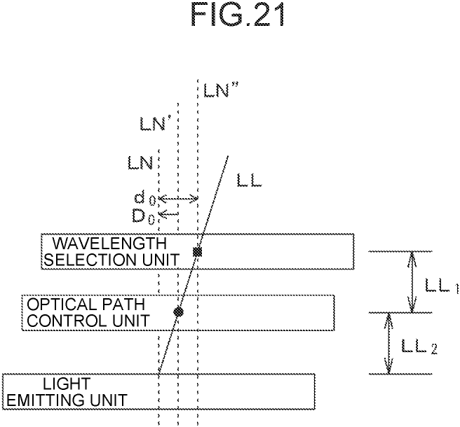

Furthermore, as illustrated in the conceptual diagram of FIG. 21, the normal line LN passing through the center of the light emitting unit, the normal line LN passing through the center of the wavelength selection unit, and the normal line LN’ passing through the center of the optical path control unit 60 may not coincide with each other, and the normal line LN’ passing through the optical path control unit 60 may not coincide with the normal line LN passing through the center of the light emitting unit and the normal line LN” the center of the wavelength selection unit. Here, the center of the wavelength selection unit is preferably located on the straight line LL connecting the center of the light emitting unit and the center of the optical path control unit 60. Specifically, when the distance from the center of the light emitting unit in the thickness direction to the center of the wavelength selection unit (indicated by a black square in FIG. 21) is LL₁, and the distance from the center of the wavelength selection unit in the thickness direction to the center of the optical path control unit 60 (indicated by a black circle in FIG. 21) is LL₂,

$${\text{d}}_{0} > {\text{D}}_{0} > 0 , \text{and}$$

considering manufacturing variations,
D₀: d₀ = LL₂: (LL₁ + LL₂) is preferably satisfied.

### Example 4

Example 4 is a modification of Examples 1 to 3, and the display device of Example 4 has a resonator structure. That is, the organic EL display device preferably has a resonator structure in order to further improve the light extraction efficiency. When the resonator structure is provided, as described above, the organic layer 33 may be used as a resonance unit and a resonator structure sandwiched between the first electrode 31 and the second electrode 32, the light reflecting layer 37 may be formed below the first electrode 31 (on the first substrate 51 side), the interlayer insulating material layer 38 may be formed between the first electrode 31 and the light reflecting layer 37, the organic layer 33 and the interlayer insulating material layer 38 may be used as the resonance unit, and the resonator structure may be sandwiched between the light reflecting layer 37 and the second electrode 32. That is, when the light reflecting layer 37 is provided on the base 26, the interlayer insulating material layer 38 is provided on the light reflecting layer 37, and the first electrode 31 is provided on the interlayer insulating material layer 38, the first electrode 31 and the interlayer insulating material layer 38 may be made of the above-described materials. The light reflecting layer 37 may or may not be connected to the contact hole (contact plug) 27.

Specifically, light emitted from the light emitting layer resonates between a first interface (alternatively, in a structure in which an interlayer insulating material layer is provided under the first electrode and a light reflecting layer is provided under the interlayer insulating material layer, a first interface constituted by an interface between the light reflecting layer and the interlayer insulating material layer) constituted by an interface between the first electrode and the organic layer and a second interface constituted by an interface between the second electrode and the organic layer, and a part of the resonated light is emitted from the second electrode. When an optical distance from the maximum light emitting position of the light emitting layer to the first interface is OL₁, an optical distance from the maximum light emitting position of the light emitting layer to the second interface is OL₂, and m₁ and m₂ are integers, a configuration can be made in which the following Formulas (1-1) and (1-2) are satisfied.

$$0.7 \left\{- {Φ}_{1} / \left(2 π\right) + {\text{m}}_{1}\right\} \leq 2 \times {\text{OL}}_{1} / λ \leq 1.2 \left\{- {Φ}_{1} / \left(2 π\right) + {\text{m}}_{1}\right\}$$

$$0.7 \left\{- {Φ}_{2} / \left(2 π\right) + {\text{m}}_{2}\right\} \leq 2 \times {\text{OL}}_{2} / λ \leq 1.2 \left\{- {Φ}_{2} / \left(2 π\right) + {\text{m}}_{2}\right\}$$

where:
λ: maximum peak wavelength of spectrum of light generated in light emitting layer (alternatively, a desired wavelength of light generated in the light emitting layer), and
Φ₁: phase shift amount (unit: radian) of light reflected at first interface. where -2Π < Φ₁ ≤ 0
Φ₂: a phase shift amount (unit: radian) of light reflected at the second interface. where -2_{Π} < Φ₂ ≤ 0.

Here, the value of m₁ is a value of 0 or more, and the value of m₂ is a value of 0 or more independently of the value of m₁. However, a form of (m₁, m₂) = (0, 0), a form of (m₁, m₂) = (0, 1), a form of (m₁, m₂) = (1, 0) , and a form of (m₁, m₂) = (1, 1) can be exemplified.

The distance L₁ from the maximum light emission position of the light emitting layer to the first interface refers to an actual distance (physical distance) from the maximum light emission position of the light emitting layer to the first interface. and the distance L₂ from the maximum light emission position of the light emitting layer to the second interface refers to an actual distance (physical distance) from the maximum light emission position of the light emitting layer to the second interface. The optical distance is also referred to as an optical path length, and generally refers to n × L when a light beam passes through a medium having a refractive index n by a distance L. The same applies to the following. Therefore, when the average refractive index is represented by nₐᵥₑ,

the following relationships are satisfied:

$${\text{OL}}_{1} = {\text{L}}_{1} \times {\text{n}}_{\text{ave}}$$

OL₂ = L₂ × nₐᵥₑ. Here, the average refractive index nₐᵥₑ is obtained by summing up the product of the refractive index and the thickness of each layer constituting the organic layer (alternatively, the organic layer, the first electrode, and the interlayer insulating material layer) and dividing the sum by the thickness of the organic layer (alternatively, the organic layer, the first electrode, and the interlayer insulating material layer).

The light emitting element may be designed by determining a desired wavelength λ (specifically, for example, a red wavelength, a green wavelength, and a blue wavelength) in the light generated in the light emitting layer and obtaining various parameters such as OL₁ and OL₂ in the light emitting element on the basis of Formulas (1-1) and (1-2).

The first electrode or the light reflecting layer and the second electrode absorb a part of the incident light and reflect the rest. Therefore, a phase shift occurs in the reflected light. The phase shift amounts Φ₁ and Φ₂ canbe obtained by measuring the values of the real number part and the imaginary number part of the complex refractive index of the material constituting the first electrode or the light reflecting layer and the second electrode using, for example, an ellipsometer and performing calculation based on these values (for example, refer to “Principles of Optic”, Max Born and Emil Wolf, 1974 (PERGAMON PRESS)). The refractive index of the organic layer, the interlayer insulating material layer, or the like, the refractive index of the first electrode, or the refractive index of the first electrode in a case where the first electrode absorbs a part of incident light and reflects the rest can also be obtained by measuring using an ellipsometer.

Examples of a material constituting the light reflecting layer include aluminum, an aluminum alloy (for example, Al—Nd. or Al—Cu), an Al/Ti laminated structure, an Al—Cu/Ti laminated structure, chromium (Cr), silver (Ag), and a silver alloy (for example, Ag—Cu, Ag—Pd—Cu, Ag—Sm—Cu), and the light reflecting layer can be formed by an electron beam vapor deposition method, a hot filament vapor deposition method, a vapor deposition method including a vacuum vapor deposition method, a sputtering method, a CVD method, and an ion plating method; a plating method (electroplating method or electroless plating method); a lift-off method; a laser ablation method; and a sol-gel method or the like. Depending on the material constituting the light reflecting layer, it is preferable to form a base layer made of TiN, for example, in order to control the crystalline state of the light reflecting layer to be formed.

As described above, in the organic EL display device having the resonator structure, actually, the red light emitting element [in some cases, a red light emitting element configured by combining an organic layer that emits white light and a red color filter layer (or a flattening layer that functions as a red color filter layer)] including the organic layer that emits white light causes red light emitted from the light emitting layer to resonate, and emits reddish light (light having a light spectrum peak in a red region) from the second electrode. In addition, a green light emitting element [in some cases, a green light emitting element configured by combining an organic layer that emits white light and a green color filter layer (or a flattening layer that functions as a green color filter layer)] including an organic layer that emits white light causes green light emitted from the light emitting layer to resonate, and emits greenish light (light having a light spectrum peak in a green region) from the second electrode. Furthermore, a blue light emitting element [in some cases, a blue light emitting element configured by combining an organic layer that emits white light and a blue color filter layer (or a flattening layer that functions as a blue color filter layer)] including an organic layer that emits white light causes blue light emitted from the light emitting layer to resonate, and emits bluish light (light having a light spectrum peak in a blue region) from the second electrode. That is, a desired wavelength λ (specifically, a red wavelength, a green wavelength, and a blue wavelength are used) of light generated in the light emitting layer may be determined, and various parameters such as OL₁ and OL₂ in each of the red light emitting element, the green light emitting element, and the blue light emitting element may be obtained on the basis of Formulas (1-1) and (1-2) to design each light emitting element. For example, paragraph [0041] of JP2012-216495 A discloses an organic EL element having a resonator structure in which an organic layer is a resonance unit, and describes that a film thickness of the organic layer is preferably 80 nm or more and 500 nm or less, and more preferably 150 nm or more and 350 nm or less because a distance from a light emitting point (light emitting surface) to a reflecting surface can be appropriately adjusted. Usually, the value of (L₁ + L₂ = L₀) differs among the red light emitting element, the green light emitting element, and the blue light emitting element.

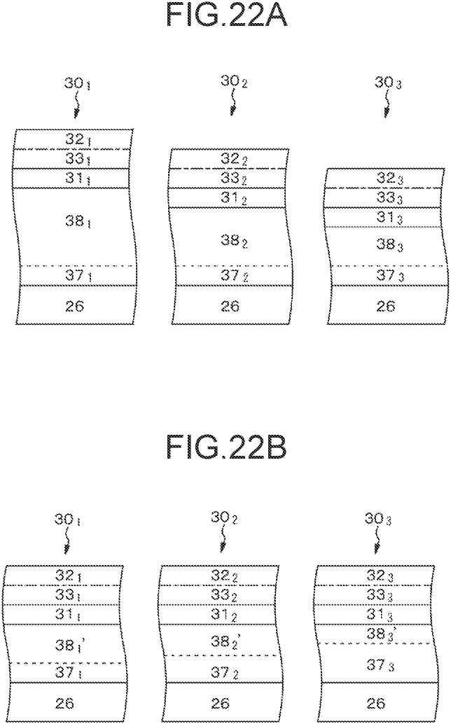

Hereinafter, the resonator structure will be described on the basis of first example to eighth example with reference to FIG. 22A (first example), 22B (second example), 23A (third example), 23B (fourth example), 24A (fifth example), 24B (sixth example), 25A (seventh example), and 25B and 25C (eighth example). Here, in the first to fourth examples and the seventh example, the first electrode and the second electrode have the same thickness in each light emitting unit. Meanwhile, in the fifth and sixth examples, the first electrode has a different thickness in each light emitting unit, and the second electrode has the same thickness in each light emitting unit. In the eighth example, the first electrode may have a different thickness in each light emitting unit or may have the same thickness, and the second electrode has the same thickness in each light emitting unit.

In the following description, the light emitting units constituting a first light emitting element 10₁, a second light emitting element 10₂, and a third light emitting element 10₃ are denoted by reference numeral 30₁, 30₂, and 30₃, the first electrode is denoted by reference numeral 31₁, 31₂, and 31₃, the second electrode is denoted by reference numeral 32₁, 32₂, and 32₃, the organic layer is denoted by reference numeral 33₁33₂, and 33₃, the light reflecting layer is denoted by reference numerals 37₁, 37₂, and 37₃, and the interlayer insulating material layer is denoted by reference numerals 38₁, 38₂, 38₃, 38₁′, 38₂′, and 38₃′. In the following description, materials to be used are examples, and can be changed as appropriate.

All of the first light emitting element 10₁, the second light emitting element 10₂, and the third light emitting element 10₃ may include the wavelength selection unit, two light emitting elements excluding one light emitting element may include the wavelength selection unit, or all of the three light emitting elements may not include the wavelength selection unit.

In the illustrated example, the resonator lengths of the first light emitting element 10₁, the second light emitting element 10₂, and the third light emitting element 10₃ derived from the formulas (1-1) and (1-2) are shortened in the order of the first light emitting element 10₁, the second light emitting element 10₂, and the third light emitting element 10₃, that is, the value of L₀ is shortened in the order of the first light emitting element 10₁, the second light emitting element 10₂, and the third light emitting element 10₃, but the present disclosure is not limited thereto, and, the optimum resonator length may be determined by appropriately setting the values of m₁ and m₂ .

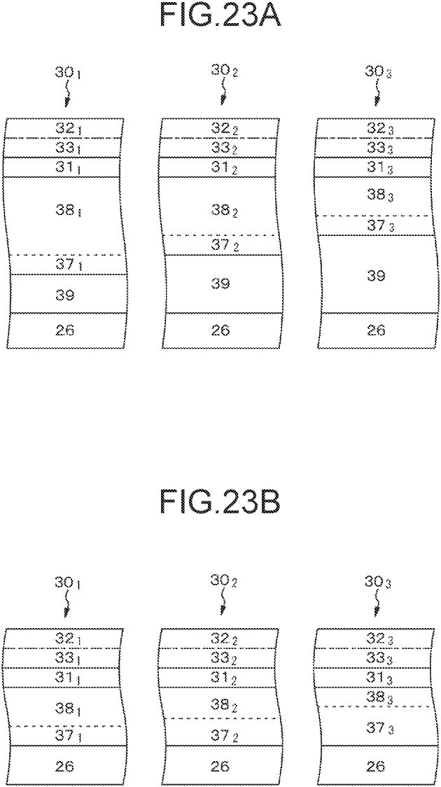

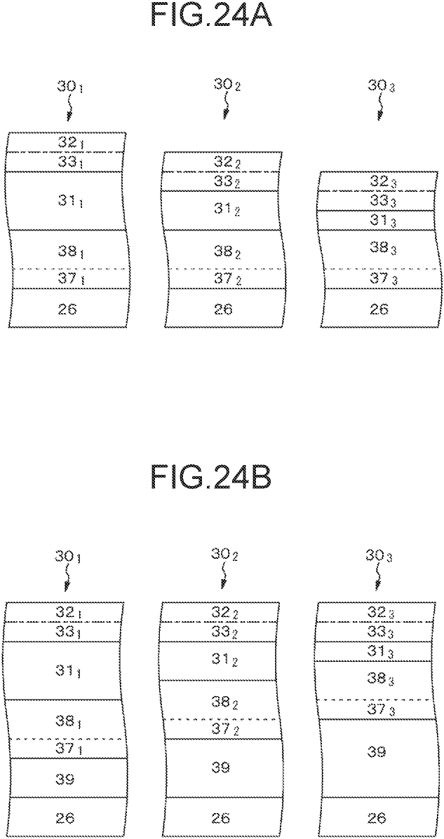

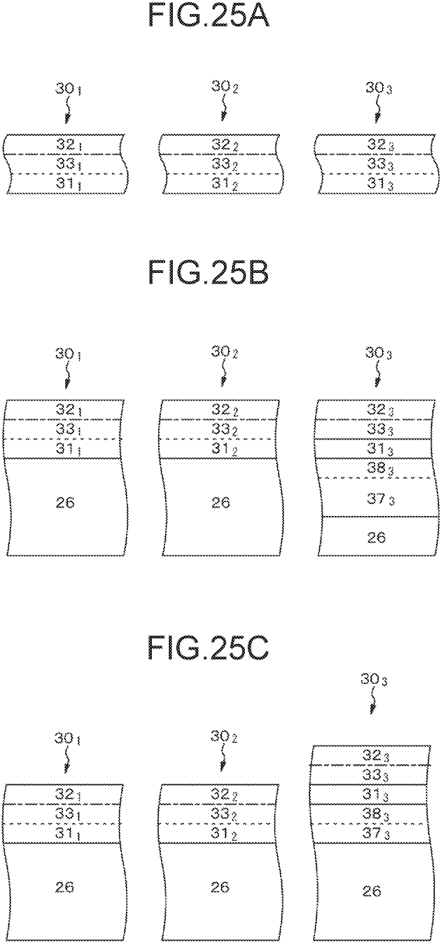

FIG. 22A illustrates a conceptual diagram of the light emitting element having the first example of a resonator structure, FIG. 22B illustrates a conceptual diagram of the light emitting element having the second example of a resonator structure, FIG. 23A illustrates a conceptual diagram of the light emitting element having the third example of a resonator structure, and FIG. 23B illustrates a conceptual diagram of the light emitting element having the fourth example of a resonator structure. In some of the first to sixth examples and the eighth example, the interlayer insulating material layers 38 and 38′ are formed under the first electrode 31 of the light emitting unit 30, and the light reflecting layer 37 is formed under the interlayer insulating material layers 38 and 38′. In the first to fourth examples, the thicknesses of the interlayer insulating material layers 38 and 38′ are different in the light emitting unit 30₁, 30₂, and 30₃. By appropriately setting the thicknesses of the interlayer insulating material layers 38₁, 38₂, 38₃, 38₁′, 38₂′, and 38₃′, it is possible to set an optical distance at which optimum resonance is generated with respect to the emission wavelength of the light emitting unit 30.

In the first example, in the light emitting unit 30₁, 30₂, and 30₃, the first interface (in the drawings, it is indicated by a dotted line) is at the same level, while the level of the second interface (in the drawings, it is indicated by an alternate long and short dash line) is different in the light emitting unit 30₁, 30₂, and 30₃. In addition, in the second example, the first interface is set to a different level in the light emitting unit 30₁, 30₂, and 30₃, while the level of the second interface is the same in the light emitting unit 30₁, 30₂, and 30₃.

In the second example, the interlayer insulating material layers 38₁′, 38₂′, and 38₃′ are made of an oxide film in which the surface of the light reflecting layer 37 is oxidized. The interlayer insulating material layer 38′ made of an oxide film is made of, for example, aluminum oxide, tantalum oxide, titanium oxide, magnesium oxide, zirconium oxide, or the like depending on the material constituting the light reflecting layer 37. The surface of the light reflecting layer 37 can be oxidized by, for example, the following method. That is, the first substrate 51 on which the light reflecting layer 37 is formed is immersed in the electrolytic solution filled in the container. A cathode is disposed so as to face the light reflecting layer 37. Then, the light reflecting layer 37 is anodized using the light reflecting layer 37 as an anode. The film thickness of the oxide film, due to anodization is proportional to a potential difference between the light reflecting layer 37 as an anode and the cathode. Therefore, the anodization is performed in a state where a voltage corresponding to the light emitting unit 30₁, 30₂, and 30₃ is applied to each of the light reflecting layers 37₁, 37₂, and 37₃. As a result, the interlayer insulating material layers 38₁′, 38₂′, and 38₃′ including oxide films having different thicknesses can be collectively formed on the surface of the light reflecting layer 37. The thicknesses of the light reflecting layers 37₁, 37₂, and 37₃ and the thicknesses of the interlayer insulating material layers 38₁′, 38₂′, and 38₃′ are different in the light emitting unit 30₁, 30₂, and 30₃.

In the third example, the base film 39 is disposed under the light reflecting layer 37, and the base film 39 has different thicknesses in the light emitting unit 30₁, 30₂, and 30₃. That is, in the illustrated example, the thickness of the base film 39 is thicker in the order of the light emitting unit 30₁, the light emitting unit 30₂, and the light emitting unit 30₃.

In the fourth example, the thicknesses of the light reflecting layers 37₁, 37₂, and 37₃ at the time of film formation are different in the light emitting units 30₁, 30₂, and 30₃. In the third and fourth examples, the second interface is at the same level in the light emitting units 30₁, 30₂, and 30₃, while the level of the first interface is different in the light emitting units 30₁, 30₂, and 30₃.

In the fifth and sixth examples, the thicknesses of the first electrode 31₁, 31₂, and 31₃ are different in the light emitting units 30₁, 30₂, and 30₃. The light reflecting layer 37 has the same thickness in each light emitting unit 30.

In the fifth example, the level of the first interface is the same in the light emitting units 30₁, 30₂, and 30₃, while the level of the second interface is different in the light emitting units 30₁, 30₂, and 30₃.

In the sixth example, the base film 39 is disposed under the light reflecting layer 37, and the base film 39 has different thicknesses in the light emitting units 30₁, 30₂, and 30₃. That is, in the illustrated example, the thickness of the base film 39 is thicker in the order of the light emitting unit 30₁, the light emitting unit 30₂, and the light emitting unit 30₃. In the sixth example, in the light emitting units 30₁, 30₂, and 30₃, the second interface is at the same level, while the level of the first interface is different in the light emitting units 30₁, 30₂, and 30₃.

In the seventh example, the first electrodes 31₁, 31₂, and 31₃ also serve as the light reflecting layer, and the optical constant (specifically, the phase shift amount) of the material constituting the first electrodes 31₁, 31₂, and 31₃ is different in the light emitting units 30₁, 30₂, and 30₃. For example, the first electrode 31₁ of the light emitting unit 30₁ may be made of copper (Cu), and the first electrode 31₂ of the light emitting unit 30₂ and the first electrode 31₃ of the light emitting unit 30₃ may be made of aluminum (Al).

In the eighth example, the first electrodes 31₁, and 31₂ also serve as the light reflecting layer, and the optical constant (specifically, the phase shift amount) of the material constituting the first electrodes 31₁, and 31₂ is different in the light emitting units 30₁, a na 30₂. For example, the first electrode 31₁ of the light emitting unit 30₁ may be made of copper (Cu) , and the first electrode 31₂ of the light emitting unit 30₂ and the first electrode 31₃ of the light emitting unit 30₃ may be made of aluminum (Al) . In the eighth example, for example, the seventh example is applied to the light emitting units 30₁, and 30₂, and the first example is applied to the light emitting unit 30₃. The thicknesses of the first electrode 31₁, 31₂, and 31₃ may be different or the same.

Although the present disclosure has been described above based on preferred examples, the present disclosure is not limited to these examples. The configurations and structures of the display (organic EL display device) and the light emitting element (organic EL element) described in Examples are examples and can be appropriately changed, and the manufacturing method of the display device is also an example and can be appropriately changed. In Examples, the drive circuit (light emitting element driving unit) is constituted by a MOSFET, but may be constituted by a TFT. The first electrode and the second electrode mayhave a single-layer structure or a multilayer structure.

In order to prevent light emitted from a certain light emitting element from entering a light emitting element adjacent to the certain light emitting element and occurrence of optical crosstalk, a light shielding portion may be provided between the light emitting element and the and light emitting element. That is, a groove portion may be formed between the light emitting element a nd the light emitting element, and the light shielding portion may be formed by embedding the groove portion with a light shielding material. When the light shielding portion is provided in this manner, it is possible to reduce a ratio at which light emitted from a certain light emitting element enters an adjacent light emitting element, and it is possibleto suppress occurrence of a phenomenon in which color mixing occurs and chromaticity of the entire pixel deviates from desired chromaticity. Then, since color mixing can be prevented, the color purity when the pixel emits light in a single color increases, and the chromaticity point is deepened. Therefore, the color gamut is widened, and the range of color representation of the display device is widened. In addition, although the color filter layer is disposed for each pixel in order to improve the color purity, depending on the configuration of the light emitting element, the color filter layer can be thinned or the color filter layer can be omitted, and the light absorbed in the color filter layer can be extracted, resulting in improvement of the light emission efficiency. Alternatively, a light shielding property may be imparted to the light absorbing layer (black matrix layer).

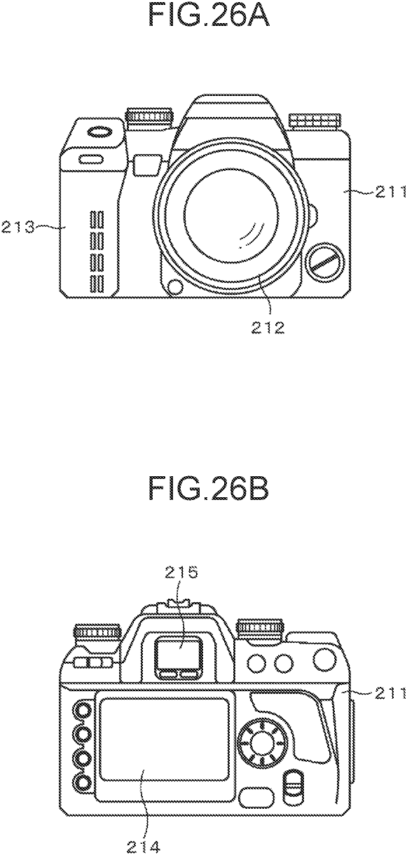

The display device of the present disclosure can be applied to a lens interchangeable single lens reflex type digital still camera. A front view of the digital still camera is illustrated in FIG. 26A, and a rear view thereof is illustrated in FIG. 26B. This lens interchangeable single lens reflex type digital still camera includes, for example, an interchangeable imaging lens unit (interchangeable lens) 212 on the front right side of a camera main body portion (camera body) 211, and a grip portion 213 to be held by a photographer on the front left side. A monitor 214 is provided substantially at the center of the back surface of the camera body 211. An electronic view finder (eyepiece window) 215 is provided above the monitor 214. By looking into the electronic view finder 215, the photographer can determine the composition by visually recognizing the optical image of the subject guided from the imaging lens unit 212. In the lens interchangeable single lens reflex type digital still camera having such a configuration, the display device of the present disclosure can be used as the electronic view finder 215.

Note that the present disclosure can also have the following configurations.

### [A01] Light Emitting Element

A light emitting element including: at least
a first electrode;
a second electrode; and
a light emitting unit sandwiched between the first electrode and the second electrode, in which the light emitting unit at least includes at least two light emitting layers that emit different colors and an intermediate layer located between the two light emitting layers,
the intermediate layer contains a first organic material having hole transport properties and a second organic material having electron transport properties, and
when a band gap energy of the first organic material is BG_{HTM}, and a band gap energy of a material having a maximum band gap energy among materials constituting adjacent two light emitting layers is BGₘₐₓ,
BG_{HTM}-BGₘₐₓ ≥ 0.2 eV is satisfied.

[A02] The light emitting element according to [A01], in which when a HOMO value of the first organic material is HOMO_{HTM}, a HOMO value of one adjacent light emitting layer is HOMO₁, and a HOMO value of the other adjacent light emitting layer is HOMO₂,
   | HOMO₂ | ≤ |HOMO_{HTM}| ≤ | HOMO₁ | is satisfied, preferably,
   | HOMO₂| < |HOMO_{HTM}| ≤ | HOMO₁ | is satisfied, more preferably,
   | HOMO₂ | < | HOMO_{HTM} | < | HOMO₁ | is satisfied.

[A03] The light emitting element according to [A01] or [A02], in which when a LUMO value of the second organic material is LUMO_{ETM}, a LUMO value of one adjacent light emitting layer is LUMO₁, and a LUMO value of the other adjacent light emitting layer is LUMO₂,
   | LUMO_{ETM}| ≤ | LUMO₁ | is satisfied,
   | LUMO_{ETM} | ≤ | LUMO₂ | is satisfied, preferably,
   | LUMO_{ETM}| < |LUMO₁| is satisfied, and
   | LUMO_{ETM} | < | LUMO₂ | is satisfied.

[A04] The light emitting element according to any one of [A01] to [A03], in which when an electron mobility of the second organic material is EM_{ETM} and an electron mobility of a material constituting one adjacent light emitting layer is EM₁,
EM₁E ≤ EM_{ETM} is satisfied, preferably,
EM₁E < EM_{ETM} is satisfied.

[A05] The light emitting element according to any one of [A01] to [A04], in which when a mass of the first organic material occupying the intermediate layer is M_{HTM}, and a mass of the second organic material occupying the intermediate layer is M_{ETM},

M_{HTM} ≥ M_{ETM} is satisfied

### [B01] Display Device

A display device including:
a plurality of light emitting elements arranged in a first direction and a second direction different from the first direction, in which each light emitting element includes : at least
   a first electrode;
   a second electrode; and
   a light emitting unit sandwiched between the first electrode and the second electrode,
      the light emitting unit at least includes at least two light emitting layers that emit different colors and an intermediate layer located between the two light emitting layers,
      the intermediate layer contains a first organic material having hole transport properties and a second organic material having electron transport properties, and
      when a band gap energy of the first organic material is BG_{HTM}, and a band gap energy of a material having a maximum band gap energy among materials constituting adjacent two light emitting layers is BGₘₐₓ,
      BG_{HTM}-BGₘₐₓ ≥ 0.2 eV is satisfied

### [B02] Display Device

A display device including:
a first substrate, a second substrate; and
a plurality of light emitting elements positioned between the first substrate and the second substrate and arranged two-dimensionally, in which each of the light emitting elements includes the light emitting element according to any one of [A01] to [A05], and
light from a light emitting unit is emitted to an outside via a second substrate or is emitted to the outside via a first substrate.

[C01] The display device according to [B01] or [B02], further including an optical path control unit through which light emitted from the light emitting unit passes, in which a reference point P is set, and

when a distance from the reference point P to a normal line passing through a center of the light emitting unit is D₁, and a distance between the normal line passing through the center of the light emitting unit and a normal line passing through a center of the optical path control unit is D₀, in at least some of the light emitting elements constituting the display panel included in the display device, a value of the distance D₀ is not 0.

[C02] The display device according to [C01], in which the distance D₀ depends on the distance D₁.

[C03] The display device according to [C01] or [C02], in which the reference point P is assumed in the display panel.

_{[}C04] The display device according to [C03], in which the reference point P is not located in a center region of the display panel.

[C05] The display device according to [C03] or [C04], in which a plurality of reference points P are assumed.

[C06] The display device according to [C03], in which in a case where one reference point P is assumed, the reference point P is not included in a center region of the display panel, and in a case where a plurality of reference points P are assumed, at least one reference point P is not included in the center region of the display panel.

[C07] The display device according to [C01] or [C02], in which the reference point P is assumed outside the display panel.

[C08] The display device according to [C07], in which a plurality of reference points P are assumed.

[C09] The display device according to any one of [C01] to [C06], in which light emitted from each light emitting element and passing through the optical path control unit converges on a certain region of a space outside the display device.

[C10] The display device according to any one of [C01] to [C06], in which the light emitted from each light emitting element and passing through the optical path control unit diverges in a space outside the display device.

[C11] The display device according to any one of [C01] to [C06], in which light emitted from each light emitting element and passing through the optical path control unit is parallel light.

[C12] The display device according to any one of [C01] to [C11], in which the plurality of light emitting elements are arranged in a first direction and a second direction different from the first direction, and
when values of the distance D₀ in the first direction and the second direction are defined as D_{0-X} and D_{0-Y}, and values of the distance D₁ in the first direction and the second direction are defined as D_{1-X} and D_{1-Y},
D₀₋ₓ changes linearly with respect to change of D_{1-X}, and D_{0-Y} changes linearly with respect to change of D_{1-Y}, or
D₀₋ₓ changes linearly with respect to the change of D₁₋_{X}, and D_{0-Y} changes nonlinearly with respect to the change of D_{1-Y}, or
D₀₋ₓ changes nonlinearly with respect to the change of D_{1-X,} and D_{0-Y} changes linearly with respect to the change of D_{1-Y}, or
D₀₋ₓ changes nonlinearly with respect to the change of D_{1-X}, and D_{0-Y} changes nonlinearly with respect to the change of D_{1-Y}.

[C13] The display device according to any one of [C01] to [C12], in which the value of the distance D₀ increases as the value of the distance D₁ increases.

[C14] The display device according to any one of [C01] to [C13], in which a wavelength selection unit is provided on a light incident side or a light emitting side of the optical path control unit.

[C15] The display device according to [C14], in which an orthogonal projection image of the optical path control unit with respect to a first substrate coincides with an orthogonal . projection image of the wavelength selection unit with respect to the first substrate, or is included in the orthogonal projection image of the wavelength selection unit with respect to the first substrate.

[C16] The display device according to [C14] or [C15], in which in the light emitting element in which the value of the distance D₀ is not 0, a normal line passing through a center of the wavelength selection unit coincides with a normal line passing through a center of the light emitting unit.

[C17] The display device according to [C14] or [C15], in which in the light emitting element in which the value of the distance D₀ is not 0, a normal line passing through the center of the wavelength selection unit coincides with a normal line passing through the center of the optical path control unit.

[C18] The display device according to [C14], in which an orthogonal projection image of the optical path control unit with respect to the first substrate is included in an orthogonal projection image of the wavelength selection unit with respect to the first substrate, and

in the light emitting element in which the value of the distance D₀ is not 0, a normal line passing through a center of the wavelength selection unit coincides with a normal line passing through a center of the light emitting unit.

[C19] The display device according to [C14], in which the orthogonal projection image of the optical path control unit with respect to the first substrate is included in the orthogonal projection image of the wavelength selection unit with respect to the first substrate, and

in the light emitting element in which the value of the distance D₀ is not 0, the normal line passing through the center of the wavelength selection unit and the normal line passing through the center of the optical path control unit coincide with each other.

[C20] The display device according to [C14], in which an orthogonal projection image of the optical path control unit with respect to the first substrate coincides with an orthogonal projection image of the wavelength selection unit with respect to the first substrate, and

in the light emitting element in which the value of the distance D₀ is not 0, a normal line passing through a center of the wavelength selection unit coincides with a normal line passing through a center of the optical path control unit.

[C21] The display device according to any one of [C14] to [C20], in which a light absorbing layer is formed between the wavelength selection units of adjacent light emitting elements.

[C22] The display device according to any one of [C01] to [C21], in which a light absorbing layer is formed between adjacent optical path control units.

[C23] The display device according to any one of [C01] to [C22], in which the light emitting unit constituting the light emitting element includes an organic electroluminescence layer.

### REFERENCE SIGNS LIST

10, 10R, 10G, 1.0B LIGHT EMITTING ELEMENT
20 TRANSISTOR
21 GATE ELECTRODE
22 GATE INSULATING LAYER
23 CHANNEL FORMATION REGION
24 SOURCE/DRAIN REGION
25 ELEMENT ISOLATION REGION
26 BASE
26A LOWER INTERLAYER INSULATING LAYER
26B UPPER INTERLAYER INSULATING LAYER
27A, 27B CONTACT HOLE (CONTACT PLUG)
27C PAD PORTION
28 INSULATING LAYER
30 LIGHT EMITTING UNIT
31 FIRST ELECTRODE
32 SECOND ELECTRODE
33 ORGANIC LAYER
33a FIRST LIGHT EMITTING LAYER
33b SECOND LIGHT EMITTING LAYER
33c THIRD LIGHT EMITTING LAYER
33d INTERMEDIATE LAYER
33e FIRST ORGANIC MATERIAL
33f SECOND ORGANIC MATERIAL
34 PROTECTIVE LAYER
35, 35′ FLATTENING LAYER
36, 36′ RESIN LAYER (SEALING RESIN LAYER)
37 LIGHT REFLECTING LAYER
38 INTERLAYER INSULATING MATERIAL LAYER
39 BASE LAYER
CF, CF_{R}, CF_{G}, CF_{B} COLOR FILTER LAYER
51 FIRST SUBSTRATE
52 SECOND SUBSTRATE
60, 61 OPTICAL PATH CONTROL UNIT
62 LIGHT REFLECTING MEMBER
BM, BM’, BM” LIGHT ABSORBING LAYER (BLACK MATRIX LAYER)

1-6. (canceled)

7. An light emitting element comprising: at least
a first electrode;
a second electrode; and
a light emitting unit sandwiched between the first electrode and the second electrode,
wherein the light emitting unit at least includes at least two light emitting layers that emit different colors and an intermediate layer located between the two light emitting layers, and
when a band gap energy of at least one of organic materials included in the intermediate layer is BG_{TM}, and a band gap energy of a material having a maximum band gap energy among materials constituting the two light emitting layers adjacent to the intermediate layer is BGₘₐₓ,
BG_{TM}-BGₘₐₓ ≥ 0.2 eV is satisfied.

8. The light emitting element according to claim 7, wherein the at least one of the organic materials included in the intermediate layer includes a first organic material having hole transport properties, and
when a HOMO value of the first organic material is HOMO_{HTM}, a HOMO value of one light emitting layer of the two light emitting layers is HOMO₁, and a HOMO value of the other light emitting layer is HOMO₂,

|HOMO₂| ≤ |HOMO_{HTM}| ≤ |HOMO₁| is satisfied.

9. The light emitting element according to claim 7, wherein the at least one of the organic materials included in the intermediate layer includes a second organic material having electron transport properties,
when a LUMO value of the second organic material is LUMO_{ETM}, a LUMO value of one light emitting layer of the two light emitting layers is LUMO₁, and a LUMO value of the other light emitting layer is LUMO₂,
at least one of |LUMO_{ETM}| ≤ |LUMO₁| and |LUMO_{ETM}| ≥ |LUMO₂| is satisfied.

10. The light emitting element according to claim 9, wherein LUMO₁ and LUMO₂ satisfy the following relationship:

|LUMO₂| ≤ |LUMO₁|.

11. The light emitting element according to claim 10, wherein LUMO_{ETM}, LUMO₁, and LUMO₂ satisfy the following relationship:

|LUMO₂| ≤ |LUMO_{ETM}| ≤ |LUMO₁|.

12. The light emitting element according to claim 7, wherein the at least one of the organic materials included in the intermediate layer includes a second organic material having electron transport properties, and
when an electron mobility of the second organic material is EM_{ETM} and an electron mobility of a material constituting one light emitting layer of the two light emitting layers is EM₁,
EM₁ < EM_{ETM} is satisfied.

13. The light emitting element according to claim 7, wherein
the intermediate layer includes a first organic material having hole transport properties and a second organic material having electron transport properties.

14. The light emitting element according to claim 13, wherein
the at least one of the organic materials included in the intermediate layer is the first organic material.

15. The light emitting element according to claim 13, wherein when a mass of the first organic material is M_{HTM} and a mass of the second organic material is M_{ETM},
M_{HTM} ≥ M_{ETM} is satisfied.

16. A display device comprising:
a plurality of light emitting elements arranged in a first direction and a second direction different from the first direction,
wherein each light emitting element includes at least
a first electrode,
a second electrode, and
a light emitting unit sandwiched between the first electrode and the second electrode,
the light emitting unit at least includes at least two light emitting layers that emit different colors and an intermediate layer located between the two light emitting layers,
when a band gap energy of at least one of organic materials included in the intermediate layer is BG_{TM}, and a band gap energy of a material having a maximum band gap energy among materials constituting the two light emitting layers adjacent to the intermediate layer is BGₘₐₓ,
BGTM-BGmax ≥ 0.2 eV is satisfied.
